(19) United States
(12) Patent Application Publication
(10) Pub. No.: US 2025/0081732 A1
(43) Pub. Date: Mar. 6, 2025

(54) Display Substrate, Manufacturing Method Therefor, and Display Device

(71) Applicants: Ordos Yuansheng Optoelectronics Co., Ltd., Ordos, Inner Mongolia (CN); BOE Technology Group Co., Ltd., Beijing (CN)

(72) Inventors: Dong XU, Beijing (CN); Rui ZHOU, Beijing (CN); Tong WU, Beijing (CN); Zihua LI, Beijing (CN); Wei ZHANG, Beijing (CN); Bo SHI, Beijing (CN)

(21) Appl. No.: 18/026,130

(22) PCT Filed: Mar. 24, 2022
(86) PCT No.: PCT/CN2022/082714

§ 371 Date: Mar. 14, 2023

(51) Int. Cl. H10K 59/122; H10K 59/12; H10K 59/121

(52) U.S. Cl. CPC H10K 59/122; H10K 59/1201; H10K 59/121

(57) ABSTRACT

A display substrate, a manufacturing method therefor and a display device are provided. The display substrate includes pixel light emitting regions and pixel spacer regions between adjacent pixel light emitting regions; in a plane perpendicular to the display substrate, the display substrate includes a base substrate and a light emitting structure layer on the base substrate, the light emitting structure layer at least includes an anode, a pixel definition layer and at least one photo spacer, a pixel opening is provided in the pixel definition layer in each pixel light emitting region, the pixel opening exposes the anode, a spacer opening is provided in the pixel definition layer in the pixel spacer region, the photo spacer is provided in the spacer opening, and an orthographic projection of the photo spacer on the base substrate is within a range of an orthographic projection of the spacer opening on the base substrate.

### CROSS-REFERENCE TO RELATED APPLICATION

The present application is a U.S. National Phase Entry of International Application PCT/CN2022/082714 having an international filing date of Mar. 24, 2022, and entitled “Display Substrate, Manufacturing Method Therefor, and Display Device”. The entire contents of the above-identified applications are hereby incorporated by reference.

### TECHNICAL FIELD

The present disclosure relates to, but is not limited to, the field of display technology, and more particularly, to a display substrate, a method for manufacturing the display substrate, and a display device.

### BACKGROUND

Organic light emitting diodes (OLEDs) and quantum-dot light emitting diodes (QLEDs), which are active light emitting display elements, have advantages such as self-luminescence, wide viewing angle, high contrast, low power consumption, very high response speed, lightness and thinness, bendability, low cost, etc. With the continuous development of display technology, display devices that use OLEDs or QLEDs as light emitting elements and use thin film transistors (TFTs) for signal control have become mainstream products in the field of display at present.

### SUMMARY

The following is a summary of subject matter described herein in detail. The summary is not intended to limit the protection scope of the claims.

A display substrate includes multiple pixel light emitting regions and multiple pixel spacer regions located between adjacent pixel light emitting regions; in a plane perpendicular to the display substrate, the display substrate includes a base substrate and a light emitting structure layer disposed on the base substrate, the light emitting structure layer at least including an anode, a pixel definition layer and at least one photo spacer, a pixel opening is provided in the pixel definition layer in each of the pixel light emitting regions, the pixel opening exposes the anode, a spacer opening is provided in the pixel definition layer in each of the pixel spacer regions, the photo spacer is provided in the spacer opening, and an orthographic projection of the photo spacer on the base substrate is within a range of an orthographic projection of the spacer opening on the base substrate.

In an exemplary embodiment, a groove is provided between a sidewall of the photo spacer and a sidewall of the spacer opening.

In an exemplary embodiment, a transverse distance between the sidewall of the photo spacer and the sidewall of the spacer opening gradually increases along a direction away from the base substrate, and the transverse distance is a dimension in a plane parallel to the display substrate.

In an exemplary embodiment, at least one anode includes a body portion and at least one protrusion, the pixel opening exposes the body portion of the anode, and there is no overlap between an orthographic projection of the groove on the base substrate and an orthographic projection of the at least one protrusion of the anode on the base substrate.

In an exemplary embodiment, an orthographic projection of the protrusion on the base substrate overlaps at least partially with the orthographic projection of the photo spacer on the base substrate, and the groove is in a shape of letter “C”, and is provided in an area other than an area where the protrusion is located.

In an exemplary embodiment, each protrusion at least includes a first protrusion and a second protrusion, a connection electrode is provided in a driving circuit layer, a first end of the first protrusion is connected to the body portion, a second end of the first protrusion is connected to a first end of the connection electrode through a via hole, a first end of the second protrusion is connected to a second end of the connection electrode through a via hole, a second end of the second protrusion extends in a direction away from the body portion, an orthographic projection of the second protrusion on the base substrate overlaps at least partially with the orthographic projection of the photo spacer on the base substrate, and an orthographic projection of the connection electrode on the base substrate overlaps at least partially with the orthographic projection of the groove on the base substrate.

In an exemplary embodiment, at least one anode includes a body portion and at least one protrusion, the pixel opening exposes the body portion of the anode, the groove is an annular groove surrounding the photo spacer, and an orthographic projection of the groove on the base substrate overlaps at least partially with an orthographic projection of the protrusion of the anode on the base substrate to form a connection overlapping region; in the connection overlapping region, a distance between a surface of the groove close to the base substrate and the base substrate is greater than a distance between a surface of the anode away from the base substrate and the base substrate.

In an exemplary embodiment, in the connection overlapping region, the protrusion has a first width, and in an area other than the connection overlapping region, the protrusion has a second width, the first width is less than the second width, and the first width and the second width are dimensions along an extension direction of the groove.

In an exemplary embodiment, the protrusion at least includes a first protrusion, a second protrusion and a third protrusion, a first end of the first protrusion is connected to the body portion, a second end of the first protrusion is connected to a first end of the third protrusion, a second end of the third protrusion is connected to a first end of the second protrusion after extending in the direction away from the body portion, a second end of the second protrusion extends in the direction away from the body portion, an orthographic projection of the second protrusion on the base substrate overlaps at least partially with the orthographic projection of the photo spacer on the base substrate, an orthographic projection of the third protrusion on the base substrate at least partially overlaps with the orthographic projection of the groove on the base substrate, the third protrusion has the first width, and the first protrusion or the second protrusion has the second width.

In an exemplary embodiment, the first width is 0.5 μm to 2 μm and the second width is 8 μm to 12 μm.

In an exemplary embodiment, the width of the surface of the groove close to the base substrate is 0.5 μm to 5.0 μm, and the width is a dimension perpendicular to an extension direction of the groove.

In an exemplary embodiment, a surface of the protrusion in the connection overlapping region has a first roughness, and a surface of the protrusion in the area other than the connection overlapping region has a second roughness, and the first roughness is greater than the second roughness.

In an exemplary embodiment, the photo spacer and the pixel definition layer are made of a same material, and are formed simultaneously through the same running of a patterning process.

In an exemplary embodiment, the display substrate further includes a driving circuit layer disposed on the base substrate, and the light emitting structure layer is disposed on one side of the driving circuit layer away from the base substrate; the driving circuit layer includes multiple circuit units constituting multiple rows of units and multiple columns of units, the multiple circuit units are arranged in alignment in the rows of units, and the multiple circuit units are arranged in alignment in the columns of units; the light emitting structure layer includes multiple sub-pixels constituting multiple rows of pixels and multiple columns of pixels, the multiple sub-pixels are arranged in alignment in the rows of pixels, and the multiple sub-pixels are arranged in a staggered manner in the columns of pixels.

In an exemplary embodiment, at least one of the circuit units includes a pixel driving circuit, the pixel driving circuit is connected to a first scan signal line, a second scan signal line and a light emitting control line respectively, the pixel driving circuit at least includes a storage capacitor, in the M-th row of units, the first scan signal line is located at one side of the storage capacitor close to the (M+1)-th row of units, the second scan signal line is located at one side of the storage capacitor away from the (M+1)-th row of units, and the light emitting control line is located between the storage capacitor and the second scan signal line; at least one of the sub-pixels includes an anode connected to the pixel driving circuit, an anode in the (2M−1)-th row of pixels is located at one side of the light emitting control line in the M-th row of units away from the (M+1)-th row of units, an anode in the 2M-th row of pixels is located at one side of the light emitting control line in the M-th row of units close to the (M+1)-th row of units, 1≤M≤K, and K is the number of the rows of units.

In an exemplary embodiment, an orthographic projection of the anode in the (2M−1)-th row of pixels on the base substrate overlaps at least partially with an orthographic projection of the second scan signal line in the M-th row of units on the base substrate, and an orthographic projection of the anode in the 2M-th row of pixels on the base substrate overlaps at least partially with an orthographic projection of the storage capacitor on the base substrate.

In an exemplary embodiment, an orthographic projection of the anode in the (2M−1)-th row of pixels on the base substrate overlaps at least partially with orthographic projections of two pixel driving circuits in the M-th row of units on the base substrate, and the orthographic projection of the anode in the 2M-th row of pixels on the base substrate overlaps at least partially with the orthographic projections of two pixel driving circuits in the M-th row of units on the base substrate.

In an exemplary embodiment, at least one photo spacer being located between adjacent anodes includes any one or more of the following cases that: at least one photo spacer is located between adjacent anodes in a row of pixels, at least one photo spacer is located between adjacent anodes in a column of pixels, and at least one photo spacer is located between the anode in the (2M−1)-th row of pixels and the anode in the 2M-th row of pixels.

In an exemplary embodiment, the at least one photo spacer is in a shape of a rectangle, which includes long sides and short sides, and the at least one photo spacer at least includes a first photo spacer with long sides extending along a direction of the columns of pixels, a second photo spacer with long sides extending along a direction of the rows of pixels, and a third photo spacer with long sides extending along an oblique direction, a first included angle is formed between the oblique direction and the direction of the columns of pixels, or a second included angle is formed between the oblique direction and the direction of the rows of pixels, and the first included angle and the second included angle are greater than 0° and less than 90°.

In an exemplary embodiment, the first photo spacer is arranged between adjacent anodes in a row of pixels, the second photo spacer is arranged between adjacent anodes in a row of pixels, and the third photo spacer is arranged between the anode in the (2M−1)-th row of pixels and the anode in the 2M-th row of pixels.

In an exemplary embodiment, an orthographic projection of the third photo spacer on the base substrate overlaps at least partially with an orthographic projection of the light emitting control line on the base substrate.

In an exemplary embodiment, multiple photo spacers constitutes multiple rows of photo spacers and multiple columns of photo spacers, and three rows of pixels correspond to four rows of photo spacers.

A display device includes the display substrate described above.

A method for manufacturing a display substrate, which includes multiple pixel light emitting regions and multiple pixel spacer regions located between adjacent pixel light emitting regions, and the method includes:
forming a light emitting structure layer on a base substrate, the light emitting structure layer at least including an anode, a pixel definition layer and at least one photo spacer, a pixel opening being provided in the pixel definition layer in each of the pixel light emitting regions, the pixel opening exposing the anode, a spacer opening being provided in the pixel definition layer in each of the pixel spacer regions, the photo spacer being provided in the spacer opening, and an orthographic projection of the photo spacer on the base substrate being within the range of an orthographic projection of the spacer opening on the base substrate.

Other aspects may become clear upon reading and understanding of the accompanying drawings and the detailed description.

### BRIEF DESCRIPTION OF DRAWINGS

Accompanying drawings are intended to provide an understanding of technical solutions of the present disclosure and form a part of the specification, and are used to explain the technical solutions of the present disclosure together with examples of the present disclosure, and not intended to form limitations on the technical solutions of the present disclosure. Shapes and sizes of various components in the drawings do not reflect actual scales, and are only intended to schematically illustrate the contents of the present disclosure.

FIG. 1 is a schematic structural diagram of an OLED display device.

FIG. 2 is a schematic sectional view of a display device.

FIG. 3 is a schematic sectional view of a display substrate.

FIG. 4 is a schematic equivalent circuit diagram of a pixel driving circuit.

FIG. 5 is a schematic diagram of a planar structure of a driving circuit layer in a display substrate in accordance with an example of the present disclosure.

FIG. 6 is a schematic diagram of a planar structure of a circuit unit in accordance with an exemplary example of the present disclosure.

FIG. 7 is a schematic diagram of a planar structure of a light emitting structure layer in a display substrate in accordance with an example of the present disclosure.

FIGS. 8a and 8b are schematic structural diagrams of a sub-pixel in accordance with an exemplary example of the present disclosure.

FIGS. 9a to 9c are schematic structural diagrams of another sub-pixel in accordance with an exemplary example of the present disclosure.

FIGS. 10a to 10c are schematic structural diagrams of another sub-pixel in accordance with an exemplary example of the present disclosure.

FIGS. 11a to 11c are schematic structural diagrams of another sub-pixel in accordance with an exemplary example of the present disclosure.

FIGS. 12a to 12c are schematic structural diagrams of another sub-pixel in accordance with an exemplary example of the present disclosure.

FIG. 13 is a schematic diagram after a pattern of a driving structure layer is formed in accordance with an exemplary example of the present disclosure.

FIGS. 14a and 14b are schematic diagrams after a pattern of an anode conductive layer is formed in accordance with an exemplary example of the present disclosure.

FIGS. 15a and 15b are schematic diagrams after a pattern of photo spacers is formed in accordance with an exemplary example of the present disclosure.

FIG. 16 is a schematic diagram of an exposure mode in accordance with an exemplary example of the present disclosure.

FIG. 17 is a schematic diagram of another exposure mode in accordance with an exemplary example of the present disclosure.

FIG. 18a is a schematic diagram of an exposure mode for a pixel definition layer and a photo spacer.

FIG. 18b is a schematic sectional view of a pixel definition layer and a photo spacer.

FIG. 19 is schematic diagram of a display substrate in which light leakage occurs.

Description of reference signs:

| | | |
|---|---|---|
| 10-base substrate; | 20-driving circuit layer; | 21-first scan signal line; |
| 22-second scan signal line | 23-light emitting control line; | 24-first plate; |
| 25-connection electrode; | 30-light emitting structure layer; | 31-anode; |
| 32-pixel definition layer; | 33-organic light emitting layer; | 34-cathode; |
| 50-photo spacer; | 60-groove; | 60-1-first sidewall; |
| 60-2-second sidewall; | 60-3-bottom wall; | 61-connection overlapping region; |
| 71-pixel opening; | 72-spacer opening; | 91-body portion; |
| 92-protrusion; | 92-1-first protrusion; | 92-2-second protrusion; |
| 92-3-third protrusion; | 93-rough surface region; | 100-halftone mask; |
| 101- non-exposure area; | 102-partial exposure area; | 103-full exposure area; |
| 200-gray tone mask; | 201-non-exposure area; | 202-first partial exposure area; |
| 203-second partial exposure area; | 204-full exposure area; | 300-display structure layer; |
| 400-cover plate glass; | 500-frit sealant. | |

### DETAILED DESCRIPTION

In order to make objects, technical solutions and advantages of the present disclosure more clear and understandable, examples of the present disclosure will be described below in detail in combination with the drawings. It should be noted that embodiments may be implemented in a number of different forms. Those of ordinary skills in the art may readily understand the fact that implementations and contents may be transformed into various forms without departing from the purpose and scope of the present disclosure. Therefore, the present disclosure should not be interpreted as being limited to the contents recorded in following embodiments only. The examples in the present disclosure and features in the examples can be randomly combined with each other if there is no conflict. In order to keep the following description of the examples of the present disclosure clear and concise, detailed descriptions of a portion of known functions and known components are omitted in the present disclosure. The drawings in the examples of the present disclosure relate only to the structures involved in the examples of the present disclosure, and other structures may be described with reference to conventional designs.

Scales of the drawings in the present disclosure can be used as references in the actual processes, but are not limited thereto. For example, a width-to-length ratio of a channel, a thickness of each film layer and a spacing between two film layers, and a width of each signal line and a spacing between two signal lines can be adjusted according to actual needs. The number of pixels in the display substrate and the number of sub-pixels in each pixel are not limited to numbers shown in the drawings. The drawings described in the present disclosure are a schematic structural diagrams only, and one implementation of the present disclosure is not limited to the shapes or numerical values shown in the drawings.

Ordinal numerals such as “first”, “second”, “third” and the like in the specification are set in order to avoid confusion between constituent elements, but not to set a limit in quantity.

For convenience, terms such as “middle”, “upper”, “lower”, “front”, “back”, “vertical”, “horizontal”, “top”, “bottom”, “inside”, “outside” and the like indicating orientation or position relationships are used in the specification to illustrate position relationships between the constituent elements with reference to the drawings, and are intended to facilitate description of the specification and simplification of the description, but not to indicate or imply that the mentioned device or element must have a specific orientation or be constructed and operated in a specific orientation, therefore, they should not be understood as limitations on the present disclosure. The position relationships between the constituent elements are appropriately changed according to directions for describing the constituent elements. Therefore, wordings used in the specification are not limited and appropriate substitutions may be made according to situations.

Unless otherwise specified and defined explicitly, terms “installed”, “coupled” and “connected” should be understood in a broad sense in the specification. For example, a connection may be a fixed connection, a detachable connection or an integrated connection, or may be a mechanical connection or an electrical connection, or may be a direct connection, an indirect connection through an intermediate component, or internal connection between two elements. Specific meanings of the above terms in the present disclosure can be understood by those of ordinary skills in the art according to specific situations.

In the specification, a transistor refers to a component which at least includes three terminals, namely a gate electrode, a drain electrode and a source electrode. The transistor has a channel region between the drain electrode (drain electrode terminal, drain region or drain) and the source electrode (source electrode terminal, source region or source), and a current can flow through the drain electrode, the channel region and the source electrode. In the specification, the channel region refers to a through region which the current mainly flows.

In the specification, a first electrode may be a drain electrode and a second electrode may be a source electrode, or the first electrode may be a source electrode and the second electrode may be a drain electrode. In the case that transistors with opposite polarities are used or the case that a current direction is changed during circuit operation, functions of the “source electrode” and the “drain electrode” are sometimes interchanged. Therefore, the “source electrode” and the “drain electrode” can be interchanged in the specification.

In the specification, “electrical connection” includes a case where constituent elements are connected together through an element with a certain electrical effect. The “element with the certain electrical effect” is not particularly limited as long as electrical signals can be sent and received between the connected constituent elements. Examples of the “element with the certain electrical action” not only include an electrode and a wiring, but also include a switching element such as a transistor, a resistor, an inductor, a capacitor, other elements with one or more functions, etc.

In the specification, “parallel” refers to a state in which an angle formed by two straight lines is above −10° and below 10°, and thus also includes a state in which the angle is above −5° and below 5°. In addition, “vertical” refers to a state in which an angle formed by two straight lines is above 80° and below 100°, and thus also includes a state in which the angle is above 85° and below 95°.

In the specification, “film” and “layer” may be interchangeable. For example, sometimes “conductive layer” may be replaced by “conductive film”. Similarly, sometimes “insulating film” may be replaced by “insulating layer”.

“Being disposed on a same layer” mentioned in the specification means that two (or more than two) structures are formed by patterning through the same running of patterning processes, and they may be made of the same or different materials. For example, materials of precursors forming multiple structures disposed on a same layer are the same, and the resulting materials may be the same or different.

Triangle, rectangle, trapezoid, pentagon and hexagon in the specification are not in the strict sense, and they may be approximate triangle, rectangle, trapezoid, pentagon or hexagon, in which there may be some small deformation caused by tolerance, or there may be chamfers, arc edges and deformation, etc.

“About” in the present disclosure means that a boundary is defined not strictly and numerical values in process and measurement error ranges are allowed.

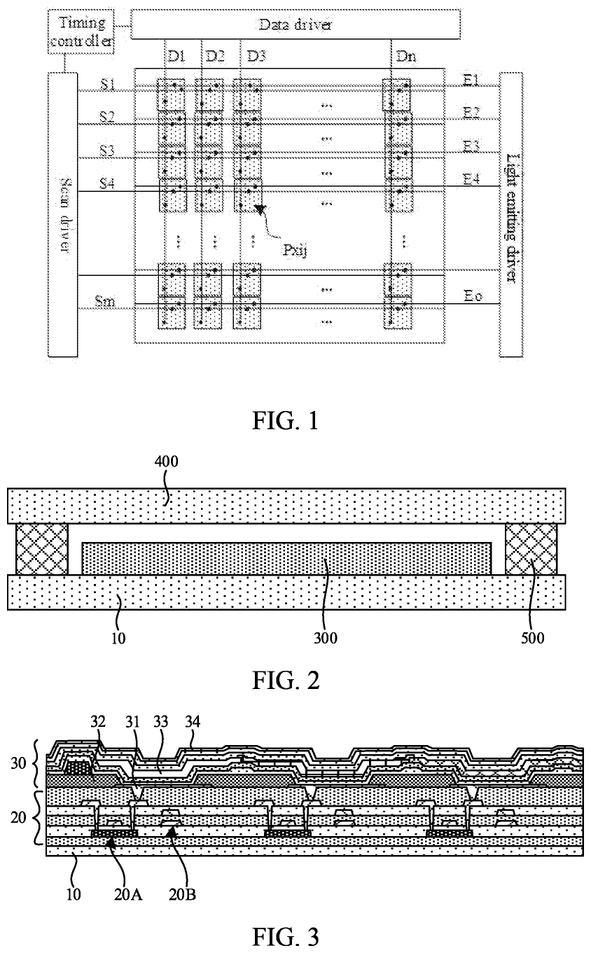

FIG. 1 is a schematic structural diagram of a display device. As shown in FIG. 1, the display device may include a timing controller, a data driver, a scan driver, a light emitting driver and a pixel array. The timing controller is connected to the data driver, the scan driver and the light emitting driver respectively. The data driver is connected to multiple data signal lines (D1 to Dn) respectively. The scan driver is connected to multiple scan signal lines (S1 to Sm) respectively. The light emitting driver is connected to multiple light emitting signal lines (E1 to Eo) respectively. The pixel array may include multiple sub-pixels Pxij, wherein i and j may be natural numbers. At least one sub-pixel Pxij may include a circuit unit and a light emitting device connected to the circuit unit. The circuit unit may include a pixel driving circuit which is connected to the scan signal line, the data signal line and the light emitting signal line, respectively. In an exemplary embodiment, the timing controller may provide the data signal driver with a grayscale value and a control signal which are suitable for the specification of the data signal driver, provide the scan driver with a clock signal and a scan start signal which are suitable for the specification of the scan driver, and provide the light emitting driver with a clock signal and an emission stop signal which are suitable for the specification of the light emitting driver. The data driver may generate data voltages to be provided to the data signal lines D1, D2, D3, . . . , and Dn using the grayscale value and the control signal that are received from the timing controller. For example, the data driver may sample the grayscale value using the clock signal and apply the data voltage corresponding to the grayscale value to the data signal lines D1 to Dn by taking a row of sub-pixels as a unit, wherein n may be a natural number. The scan driver may generate a scan signals to be provided to the scan signal lines S1, S2, S3, . . . , and Sm by receiving the clock signal and the scan start signal from the timing controller. For example, the scan driver may sequentially provide a scan signal with on-level pulses to the scan signal lines S1 to Sm. For example, the scan driver may be constructed in a form of a shift register and generate the scan signal by sequentially transmitting the scan start signal provided in the form of on-level pulses to a next-stage circuit under the control of the clock signal, wherein m may be a natural number. The light emitting driver may generate an emission signal to be provided to the light emitting signal lines E1, E2, E3, . . . , and Eo by receiving the clock signal and the emission stop signal from the timing controller. For example, the light emitting driver may sequentially provide an emission signal with off-level pulse to the light emitting signal lines E1 to Eo. For example, the light emitting driver may be constructed in the form of a shift register and generate the emission signal by sequentially transmitting the emission stop signal provided in the form of off-level pulses to a next-stage circuit under the control of the clock signal, wherein o may be a natural number.

FIG. 2 is a schematic sectional view of a display device, which illustrates an encapsulation mode in which a frit sealant is bonded to a cover plate glass. As shown in FIG. 2, in a plane perpendicular to the display device, a main structure of the display device may include a base substrate 10, a display structure layer 300, a cover plate glass 400 and a frit sealant 500. The display structure layer 300, disposed on the rigid base substrate 10, is configured to emit light. The display structure layer 300 may be referred to as a display substrate. The cover plate glass 400, disposed on one side of the display structure layer 300 away from the base substrate 10, is configured to implement encapsulation by the frit sealant 500. The frit sealant 500 is disposed between the base substrate 10 and the cover plate glass 400 and is fixedly bonded to the base substrate 10 and the cover plate glass 400, respectively, so that the base substrate 10, the frit sealant 500 and the cover plate glass 400 form an accommodation space to accommodate the display structure layer 300 in the accommodation space. In an exemplary embodiment, multiple photo spacers, which are configured to support the cover plate glass together with the frit sealant, may be provided on the display structure layer 300.

FIG. 3 is a schematic sectional view of a display substrate. As shown in FIG. 3, in a plane perpendicular to the display substrate, the display substrate may at least include a driving circuit layer 20 disposed on a base substrate 10 and a light emitting structure layer 103 disposed on one side of the driving circuit layer 20 away from the base substrate 10. In some possible implementations, the display substrate may include other film layers, and the present disclosure is not limited thereto.

In an exemplary embodiment, the base substrate 10 may be a rigid base substrate. The driving circuit layer 20 may include multiple circuit units arranged regularly, each of the circuit units may at least include a pixel driving circuit connected to signal lines such as a scan signal line, a data signal line and a light emitting control line, respectively. The light emitting structure layer 30 may include multiple light emitting devices arranged regularly, each of the light emitting devices may at least include an anode 31, an organic light emitting layer 33 and a cathode 34. The pixel driving circuit is configured to, under the control of the scan signal line and the light emitting signal line, receive a data voltage transmitted by the data signal line and output a corresponding current to a light emitting device, which is configured to emit light of corresponding luminance in response to a current output by the pixel driving circuit to which the light emitting device is connected.

In an exemplary embodiment, the pixel driving circuit of the circuit unit may include multiple transistors and a storage capacitor. The pixel driving circuit including one transistor 20A and one storage capacitor 20B is described by way of example in FIG. 3. The anode 31 of the light emitting device is connected to a drain electrode of the transistor 20A through a via hole, the organic light emitting layer 33 is connected to the anode 31, the cathode 34 is connected to the organic light emitting layer 33, and the organic light emitting layer 33 emits light of a corresponding color under driving of the anode 31 and the cathode 34.

In an exemplary embodiment, the light emitting structure layer 30 may further include a pixel definition layer 32, and a pixel opening is provided on the pixel definition layer 32. The pixel opening exposes the anode 31 of the light emitting device to form a light emitting area. The organic light emitting layer 33 may include a light emitting layer (EML) and any one or more of a hole injection layer (HIL), a hole transport layer (HTL), an electron block layer (EBL), a hole block layer (HBL), an electron transport layer (ETL) and an electron injection layer (EIL). In an exemplary embodiment, one or more of hole injection layers, hole transport layers, electron block layers, hole block layers, electron transport layers and electron injection layers of all sub-pixels may be connected together to form a common layer. The light emitting layers of adjacent sub-pixels may overlap slightly with each other, or may be isolated from each other.

In some possible exemplary embodiments, the base substrate may be a flexible base substrate, and the display substrate may include a thin film encapsulation layer disposed on one side of the light emitting layer away from the base substrate. The thin film encapsulation layer may include a first encapsulation layer, a second encapsulation layer and a third encapsulation layer that are stacked. The first encapsulation layer and the third encapsulation layer may be made of inorganic materials, and the second encapsulation layer may be made of an organic material. The second encapsulation layer is disposed between the first encapsulation layer and the third encapsulation layer so as to ensure that external moisture cannot enter the light emitting structure layer.

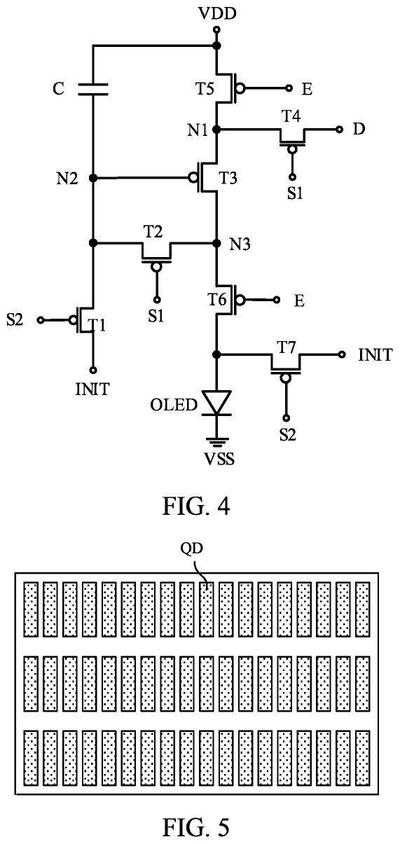

FIG. 4 is a schematic equivalent circuit diagram of a pixel driving circuit. In an exemplary embodiment, the pixel driving circuit may be in a structure of 3T1C, 4T1C, 5T1C, 5T2C, 6T1C, 7T1C or 8T1C. As shown in FIG. 4, the pixel driving circuit may include seven transistors (a first transistor T1 to a seventh transistor T7) and one storage capacitor C. The pixel driving circuit may be connected to seven signal lines (a data signal line D, a first scan signal line S1, a second scan signal line S2, a light emitting signal line E, an initial signal line INIT, a first power supply line VDD and a second power supply line VSS).

In an exemplary embodiment, the pixel driving circuit may include a first node N1, a second node N2 and a third node N3. The first node N1 is connected to a first electrode of the third transistor T3, a second electrode of the fourth transistor T4 and a second electrode of the fifth transistor T5 respectively. The second node N2 is connected to a second electrode of the first transistor, a first electrode of the second transistor T2, a control electrode of the third transistor T3 and a second end of the storage capacitor C respectively. The third node N3 is connected to a second electrode of the second transistor T2, a second electrode of the third transistor T3 and a first electrode of the sixth transistor T6 respectively.

In an exemplary embodiment, a first end of the storage capacitor C is connected to the first power supply line VDD, and the second end of the storage capacitor C is connected to the second node N2, i.e., the second end of the storage capacitor C is connected to the control electrode of the third transistor T3.

A control electrode of the first transistor T1 is connected to the second scan signal line S2, a first electrode of the first transistor T1 is connected to the initial signal line INIT, and the second electrode of the first transistor is connected to the second node N2. When a scan signal with an on-level is applied to the second scan signal line S2, the first transistor T1 transmits an initialization voltage to the control electrode of the third transistor T3 so as to initialize the quantity of charge of the control electrode of the third transistor T3.

A control electrode of the second transistor T2 is connected to the first scan signal line S1, the first electrode of the second transistor T2 is connected to the second node N2, and the second electrode of the second transistor T2 is connected to the third node N3. When a scan signal with an on-level is applied to the first scan signal line S1, the second transistor T2 causes the control electrode of the third transistor T3 to be connected to the second electrode of the third transistor T3.

The control electrode of the third transistor T3 is connected to the second node N2, i.e., the control electrode of the third transistor T3 is connected to the second end of the storage capacitor C, the first electrode of the third transistor T3 is connected to the first node N1, and the second electrode of the third transistor T3 is connected to the third node N3. The third transistor T3 may be referred to as a driving transistor, and the third transistor T3 determines a magnitude of a driving current flowing between the first power supply line VDD and the second power supply line VSS according to a potential difference between the control electrode and the first electrode of the third transistor T3.

A control electrode of the fourth transistor T4 is connected to the first scan signal line S1, a first electrode of the fourth transistor T4 is connected to the data signal line D, and the second electrode of the fourth transistor T4 is connected to the first node N1. The fourth transistor T4, may be referred to as a switching transistor, a scanning transistor, etc., and the fourth transistor T4 inputs a data voltage of the data signal line D to the pixel driving circuit when a scan signal with an on-level is applied to the first scan signal line S1.

A control electrode of the fifth transistor T5 is connected to the light emitting signal line E, a first electrode of the fifth transistor T5 is connected to the first power supply line VDD, and the second electrode of the fifth transistor T5 is connected to the first node N1. A control electrode of the sixth transistor T6 is connected to the light emitting signal line E, the first electrode of the sixth transistor T6 is connected to the third node N3, and a second electrode of the sixth transistor T6 is connected to a first electrode of a light emitting device. The fifth transistor T5 and the sixth transistor T6 may be referred to as light emitting transistors. When an emission signal with an on-level is applied to the light emitting signal line E, the fifth transistor T5 and the sixth transistor T6 cause the light emitting device to emit light by forming a driving current path between the first power supply line VDD and the second power supply line VSS.

A control electrode of the seventh transistor T7 is connected to the second scan signal line S2, a first electrode of the seventh transistor T7 is connected to the initial signal line INIT, and a second electrode of the seventh transistor T7 is connected to the first electrode of the light emitting device. When a scan signal with an on-level is applied to the second scan signal line S2, the seventh transistor T7 transmits an initialization voltage to the first electrode of the light emitting device so as to initialize the quantity of charge accumulated in the first electrode of the light emitting device or release the quantity of charge accumulated in the first electrode of the light emitting device.

In an exemplary embodiment, a second electrode of the light emitting device is connected to the second power supply line VSS, a signal of the second power supply line VSS is a low-level signal, and a signal of the first power supply line VDD is a high-level signal continuously provided. The first scan signal line S1 is a scan signal line in a pixel driving circuit in a current display row, and the second scan signal line S2 is a scan signal line in a pixel driving circuit in a previous display row, that is, for the n-th display row, the first scan signal line S1 is S(n), and the second scan signal line S2 is S(n−1). The second scan signal line S2 in the pixel driving circuit in the current display row and the first scan signal line S1 in the pixel driving circuit in the previous display row are the same signal line, such that signal lines of a display panel can be reduced, so as to achieve a narrow bezel of the display panel.

In an exemplary embodiment, the first transistor T1 to the seventh transistor T7 may be P-type transistors or N-type transistors. Using the same type of transistors in the pixel driving circuit may simplify process flows, reduce process difficulties of the display panel, and improve product yield rate. In some possible implementations, the first transistor T1 to the seventh transistor T7 may include P-type transistors and N-type transistors.

In an exemplary embodiment, the first transistor T1 to the seventh transistor T7 may be low temperature poly-silicon thin film transistors, or may be oxide thin film transistors, or may be low temperature poly-silicon thin film transistors and oxide thin film transistors. Active layers of the low temperature poly-silicon thin film transistors may be made of low temperature poly-silicon (LTPS), and active layers of the oxide thin film transistors may be made of oxide semiconductor (oxide). The low temperature poly-silicon thin film transistors have advantages such as high migration rate and fast charging, and the oxide thin film transistors have advantages such as low leakage current. The low temperature poly-silicon thin film transistors and the oxide thin film transistors are integrated on one display substrate to form a low temperature polycrystalline oxide (LTPO) display substrate, so that the advantages of both the low temperature poly-silicon thin film transistors and the oxide thin film transistors can be utilized, low-frequency driving can be realized, power consumption can be decreased, and display quality can be improved.

In an exemplary embodiment, the first scan signal line S1, the second scan signal line S2, the light emitting signal line E and the initial signal line INIT can extend along a horizontal direction, and the second power supply line VSS, the first power supply line VDD and the data signal line D can extend along a vertical direction.

In an exemplary embodiment, the light emitting device may be an organic light emitting diode (OLED) including a first electrode (anode), an organic light emitting layer and a second electrode (cathode) that are stacked.

In an exemplary embodiment, taking all of the seven transistors being N-type transistors as an example, a working process of the pixel driving circuit may include the following stages.

In a first stage A1, referred to as a reset stage, a signal of the second scan signal line S2 is a low-level signal, and signals of the first scan signal line S1 and the light emitting signal line E are high-level signals. The signal of the second scan signal line S2 is the low-level signal so that the first transistor T1 is turned on, and a signal of the initial signal line INIT is provided to the second node N2 to initialize (reset) the storage capacitor C to clear original charge in the storage capacitor. The signal of the first scan signal line S2 is the low-level signal so that the seventh transistor T7 is turned on, and an initial voltage of the initial signal line INIT is provided to a first electrode of the OLED to initialize the first electrode of the OLED and clear its internal pre-stored voltage, to complete the initialization. The signals of the first scan signal line S1 and the light emitting signal line E are the high-level signals, so that the second transistor T2, the fourth transistor T4, the fifth transistor T5, the sixth transistor T6 and the seventh transistor T7 are turned off, therefore the OLED does not emit light in this stage.

In a second stage A2, referred to as a data writing stage or a threshold compensation stage, the signal of the first scan signal line S1 is a low-level signal, the signals of the second scan signal line S2 and the light emitting signal line E are high-level signals, and the data signal line D outputs a data voltage. In this stage, the second end of the storage capacitor C is at a low level, so that the third transistor T3 is turned on. The signal of the first scan signal line S1 is the low-level signal, so that the second transistor T2 and the fourth transistor T4 are turned on. The second transistor T2 and the fourth transistor T4 are turned on, so that the data voltage output by the data signal line D is provided to the second node N2 through the first node N1, the turned-on third transistor T3, the third node N3 and the turned-on second transistor T2, and a difference between the data voltage output by the data signal line D and a threshold voltage of the third transistor T3 is charged into the storage capacitor C. A voltage at the second end (the second node N2) of the storage capacitor C is Vd−|Vth|, with Vd being the data voltage output by the data signal line D, and Vth being the threshold voltage of the third transistor T3. The signal of the second scan signal line S2 is the high-level signal, so that the first transistor T1 and the seventh transistor T7 are turned off. The signal of the light emitting signal line E is the high-level signal, so that the fifth transistor T5 and the sixth transistor T6 are turned off.

In a third stage A3, referred to as a light emitting stage, the signal of the light emitting signal line E is a low-level signal, and the signals of the first scan signal line S1 and the second scan signal line S2 are high-level signals. The signal of the light emitting signal line E is the low-level signal, so that the fifth transistor T5 and the sixth transistor T6 are turned on, and a power supply voltage output by the first power supply line VDD provides a driving voltage to the first electrode of the OLED through the turned-on fifth transistor T5, third transistor T3, and sixth transistor T6 to drive the OLED to emit light.

In a driving process of the pixel driving circuit, a driving current flowing through the third transistor T3 (driving transistor) is determined by a voltage difference between a gate electrode and the first electrode of the third transistor T3. Because a voltage of the second node N2 is Vdata−|Vth|, the driving current of the third transistor T3 is:

$$I = K * {( V gs - V th )}^{2} = K * {[ ( V dd - V d + \vert V th \vert ) - V th ]}^{2} = K * {[ ( V dd - V d ]}^{2} ,$$

wherein I is the driving current flowing through the third transistor T3, i.e., a driving current for driving the OLED, K is a constant, Vgs is the voltage difference between the gate electrode and the first electrode of the third transistor T3, Vth is the threshold voltage of the third transistor T3, Vd is the data voltage output by the data signal line D, and Vdd is the power supply voltage output by the first power supply line VDD.

FIG. 5 is a schematic diagram of a planar structure of a driving circuit layer in a display substrate in accordance with an exemplary example of the present disclosure. As shown in FIG. 5, in the exemplary embodiment, in a plane parallel to the display substrate, the driving circuit layer may include multiple circuit units QD, and at least one of the multiple circuit units QD may include a pixel driving circuit configured to output a corresponding current to a light emitting device to which the pixel driving circuit is connected, so as to cause the light emitting device to emit light of corresponding luminance.

In an exemplary embodiment, the multiple circuit units QD may constitute multiple rows of pixels and multiple columns of pixels. Multiple circuit units QD sequentially arranged along the horizontal direction may be referred to as a row of units, and multiple circuit units QD sequentially arranged along the vertical direction may be referred to as a column of units. Multiple rows of units and multiple columns of units constitute an array of circuit units. In an exemplary embodiment, the driving circuit layer may include K rows of units, with K being a positive integer greater than 1.

In an exemplary embodiment, the multiple circuit units QD may be sequentially arranged in alignment in a direction of the rows of units and multiple circuit units QD may be sequentially arranged in alignment in a direction of the columns of units, to form a horizontally aligned and vertically aligned layout.

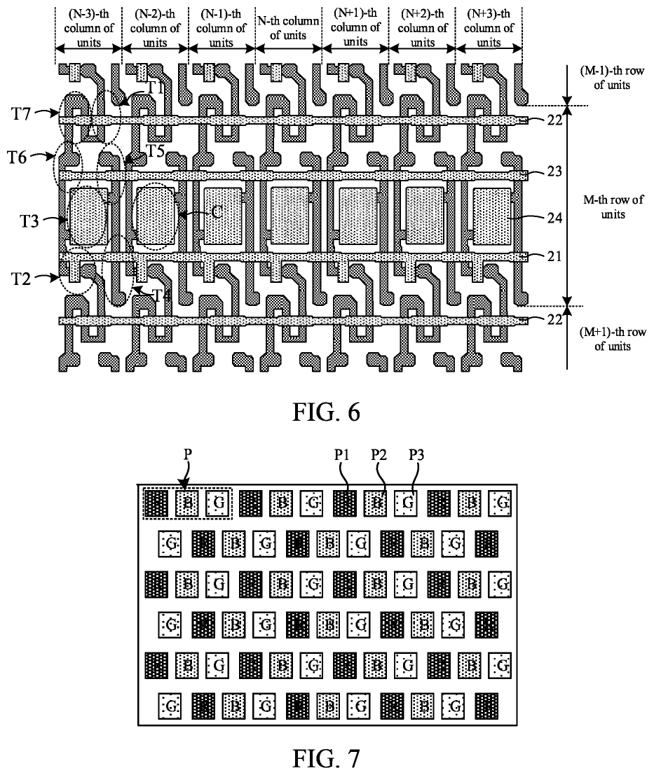

FIG. 6 is a schematic diagram of a planar structure of a circuit unit in accordance with an exemplary example of the present disclosure, which illustrates a structure of pixel driving circuits in 3 rows of units and 7 columns of units. As shown in FIG. 6, at least one circuit unit may include a pixel driving circuit which may be connected to multiple signal lines. In an exemplary embodiment, the multiple signal lines may at least include a first scan signal line 21, a second scan signal line 22 and a light emitting control line 23 extending along the horizontal direction, the pixel driving circuit may at least include a storage capacitor C and seven transistors (a first transistor T1, a second transistor T2, a third transistor T3, a fourth transistor T4, a fifth transistor T5, a sixth transistor T6 and a seventh transistor T7), and the storage capacitor C includes at least a first plate 24.

In an exemplary embodiment, in a plane perpendicular to the display substrate, the at least one circuit unit may at least include a first insulating layer, a semiconductor layer, a second insulating layer, a first conductive layer, a third insulating layer, a second conductive layer, a fourth insulating layer and a third conductive layer that are stacked on the base substrate. The semiconductor layer may at least include active layers of the first transistor T1 to the seventh transistor T7. The first conductive layer may at least include gate electrodes of the first transistor T1 to the seventh transistor T7 and the first plate of the storage capacitor C. The second conductive layer may at least include a second plate of the storage capacitor C and an initial signal line. The third conductive layer may at least include a data signal line, a first power supply line, and first electrodes and second electrodes of the first transistor T1 to the seventh transistor T7. In order to illustrate a position of each of the transistors clearly, only a part of structures of the semiconductor layer and the first conductive layer are illustrated in FIG. 7.

In an exemplary embodiment, the semiconductor layer of each circuit unit may at least include a first active layer of the first transistor T1 to a seventh active layer of the seventh transistor T7. The first active layer to the seventh active layer are connected to each other to form an integrated structure, and the second active layer of a circuit unit in the M-th row of units and the first active layer of a circuit unit in the (M+1)-th row of units in each column of units are connected to each other, that is, the semiconductor layers of adjacent circuit units in each column of units are connected to each other to form an integrated structure, 1≤M≤K, with K being the number of rows of units.

In an exemplary embodiment, the active layer of each transistor may include a first region, a second region and a channel region located between the first region and the second region. In an exemplary embodiment, the first region of the first active layer, which may serve as the first region of the seventh active layer, is configured to be connected to the initial signal line. The second region of the first active layer may also serve as the first region of the second active layer, the first region of the third active layer may serve as both the second region of the fourth active layer and the second region of the fifth active layer, the second region of the third active layer may serve as both the second region of the second active layer and the first region of the sixth active layer, and the second region of the sixth active layer may serve as the second region of the seventh active layer. The first region of the fourth active layer, which may be provided separately, is configured to be connected to the data signal line. The first region of the fifth active layer, which may be provided separately, is configured to be connected to the first power supply line.

In an exemplary embodiment, the first scan signal line 21, the second scan signal line 22 and the light emitting control line 23 may be arranged on the first conductive layer, and they may be in the shape of a line which has a body portion extending along the horizontal direction. The storage capacitor C may be located between the first scan signal line 21 and the light emitting control line 23. The first scan signal line 21 in the M-th row of units may be located at one side of the storage capacitor C close to the (M+1)-th row of units, the second scan signal line 22 may be located at one side of the storage capacitor C away from the (M+1)-th row of units, and the light emitting control line 23 may be located between the storage capacitor C and the second scan signal line 22.

In the present disclosure, “close to” and “away from” are described at the angle of an orthographic projection on the base substrate. For example, an orthographic projection of A on the base substrate is abbreviated A projection for short, an orthographic projection of B on the base substrate is abbreviated B projection for short, and an orthographic projection of D on the base substrate is abbreviated D projection for short. “A is located at one side of D close to B” means that A projection is located at one side of D projection close to B projection.

In an exemplary embodiment, the first plate 24 of the storage capacitor C may serve as the gate electrode of the third transistor (driving transistor), areas in which the first scan signal line 21 overlaps with the second active layer and the fourth active layer respectively may serve as the gate electrode of the second transistor T2 and the gate electrode of the fourth transistor T4 respectively, areas in which the second scan signal line 22 overlaps with the first active layer and the seventh active layer respectively may serve as the gate electrode of the first transistor T1 and the gate electrode of the seventh transistor T7 respectively, and areas in which the light emitting control line 23 overlaps with the fifth active layer and the sixth active layer respectively may serve as the gate electrode of the fifth transistor T5 and the gate electrode of the sixth transistor T6 respectively.

In an exemplary embodiment, the first transistor T1, the fifth transistor T5, the sixth transistor T6 and the seventh transistor T7 of the pixel driving circuit in the M-th row of units may be located at one side of the storage capacitor C away from the (M+1)-th row of units, and the second transistor T2 and the fourth transistor T4 may be located at one side of the storage capacitor C close to the (M+1)-th row of units.

In an exemplary embodiment, the fourth transistor T4 and the fifth transistor T5 of the pixel driving circuit in the N-th column of units may be located at one side of the storage capacitor C close to the (N+1)-th column of units, and the second transistor T2 and the sixth transistor T6 may be located at one side of the storage capacitor C away from the (N+1)-th column of units, with N being a positive integer greater than or equal to 1.

Multiple pixel driving circuits in each row of circuits have a same shape and are arranged in alignment. The pixel driving circuits in the M-th row of pixels and the pixel driving circuits in the (M+1)-th row of pixels have a same shape and are arranged in alignment.

FIG. 7 is a schematic diagram of a planar structure of a light emitting structure layer in a display substrate in accordance with an exemplary example of the present disclosure. As shown in FIG. 7, in a plane parallel to the display substrate, the light emitting structure layer may include multiple pixel units P arranged in a matrix. At least one of the multiple pixel units P may include a first sub-pixel P1 emitting light of a first color, a second sub-pixel P2 emitting light of a second color and a third sub-pixel P3 emitting light of a third color. The three sub-pixels may each include a light emitting device. The light emitting devices of the three sub-pixels are connected respectively to pixel driving circuits in the corresponding circuit units respectively. The light emitting deice is configured to emit light of corresponding luminance in response to a currents output by the pixel driving circuit to which the light emitting device is connected.

In an exemplary embodiment, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light. The three sub-pixels may be in a shape of a triangle, a rectangle, a rhombus, a pentagon or a hexagon, the present disclosure is not limited thereto.

In an exemplary embodiment, multiple sub-pixels may constitute multiple rows of pixels and multiple columns of pixels. Multiple sub-pixels sequentially arranged along the horizontal direction are referred to as a row of pixels, and multiple sub-pixels sequentially arranged along the vertical direction are referred to as a column of pixels. The multiple rows of pixels and the multiple columns of pixels constitute a pixel array. In an exemplary embodiment, the light emitting structure layer may include 2K rows of pixels, with K being the number of rows of units in a driving circuit layer.

In an exemplary embodiment, in the direction of the rows of pixels, the first sub-pixel P1, the second sub-pixel P2 and the third sub-pixel P3 may be sequentially arranged in alignment, and in the direction of the columns of pixels, the first sub-pixel P1, the second sub-pixel P2 and the third sub-pixel P3 may be sequentially arranged in a staggered manner to form a “triangle”-shaped layout of sub-pixels. For example, the first sub-pixel P1 in an odd-numbered row may be located between its adjacent second sub-pixel P2 and third sub-pixel P3 in even-numbered rows, or the first sub-pixel P1 in an even-numbered row may be located between its adjacent second sub-pixel P2 and third sub-pixel P3 in odd-numbered rows. As another example, the second sub-pixel P2 in an odd-numbered row may be located between its adjacent first sub-pixel P1 and third sub-pixel P3 in even-numbered rows, or the second sub-pixel P2 in an even-numbered row may be located between its adjacent first sub-pixel P1 and third sub-pixel P3 in odd-numbered rows. As another example, the third sub-pixel P3 in an odd-numbered row may be located between its adjacent first sub-pixel P1 and second sub-pixel P2 in even-numbered rows, or the third sub-pixel P3 in an even-numbered row may be located between its adjacent first sub-pixel P1 and second sub-pixel P2 in odd-numbered rows.

In an exemplary embodiment, the multiple pixel units P may constitute a “triangle”-shaped layout of pixel units.

The circuit units mentioned in the present disclosure are areas divided according to the driving circuit layer, and each circuit unit includes a pixel driving circuit. The sub-pixels mentioned in the present disclosure are areas divided according to the light emitting structure layer, and each sub-pixel includes a light emitting device. In an exemplary embodiment, positions of the sub-pixels may or may not be corresponding to positions of the circuit units.

In an exemplary embodiment, each sub-pixel may include a light emitting area and a non-light emitting area. In the present disclosure, the light emitting area of each sub-pixel is referred to as a pixel light emitting region, and the non-light emitting area of each sub-pixel is referred to as a pixel spacer region. In an exemplary embodiment, a pixel opening exposing an anode is provided in the pixel definition layer of each sub-pixel, such that an organic light emitting layer is connected to the anode through the pixel opening. Since the organic light emitting layer emits light in a pixel opening area defined by the pixel definition layer, the pixel opening area is the pixel light emitting region, and an area other than the pixel opening area is the pixel spacer region, which is located at a periphery of the light emitting region. For example, the pixel opening areas in the first sub-pixel and the second sub-pixel are pixel light emitting regions, and an area between the pixel light emitting region of the first sub-pixel and the pixel light emitting region of the second sub-pixel is a pixel spacer region. Thus, the display substrate may include multiple pixel light emitting regions arranged periodically and multiple pixel spacer regions located between adjacent pixel light emitting regions.

In an exemplary embodiment, the light emitting structure layer may include a light emitting device, a pixel definition layer and at least one photo spacer (PS). The light emitting device may include an anode, an organic light emitting layer and a cathode, and the at least one photo spacer may be disposed in the pixel spacer region. In an exemplary embodiment, for an encapsulation mode in which a frit sealant is bonded to a cover plate glass, the photo spacer is configured to support the cover plate glass.

An exemplary embodiment of the present disclosure provides a display substrate. In an exemplary embodiment, in the plane parallel to the display substrate, the display substrate may include multiple pixel light emitting regions and multiple pixel spacer regions located between adjacent pixel light emitting regions. In a plane perpendicular to the display substrate, the display substrate includes a base substrate and a driving circuit layer disposed on the base substrate and a light emitting structure layer disposed on one side of the driving circuit layer away from the base substrate. The light emitting structure layer at least includes an anode, a pixel definition layer and at least one photo spacer. A pixel opening is provided in the pixel definition layer in each of the pixel light emitting regions, the pixel opening exposes the anode, a spacer opening is provided in the pixel definition layer in each of the pixel spacer regions, a photo spacer is provided in the spacer opening, and an orthographic projection of the photo spacer on the base substrate is within a range of an orthographic projection of the spacer opening on the base substrate.

In an exemplary embodiment, a groove is provided between a sidewall of the photo spacer and a sidewall of the spacer opening.

In an exemplary embodiment, a transverse distance between the sidewall of the photo spacer and the sidewall of the spacer opening gradually increases along a direction away from the base substrate, and the transverse distance is a dimension in the plane parallel to the display substrate.

In an exemplary embodiment, the photo spacer and the pixel definition layer are made of a same material, and are formed simultaneously through the same running of patterning processes.

In an exemplary embodiment, at least one anode includes a body portion and a protrusion, the pixel opening exposes the body portion of the anode, and there is no overlap between an orthographic projection of the groove on the base substrate and an orthographic projection of the protrusion of the anode on the base substrate.

In another exemplary embodiment, at least one anode includes a body portion and a protrusion, the pixel opening exposes the body portion of the anode, the groove is an annular groove surrounding the photo spacer, and the orthographic projection of the groove on the base substrate overlaps at least partially with the orthographic projection of the protrusion of the anode on the base substrate to form a connection overlapping region. In the connection overlapping region, a distance between a surface of the groove close to the base substrate and the base substrate is greater than a distance between a surface of the anode away from the base substrate and the base substrate.

In another exemplary embodiment, in the connection overlapping region, the protrusion has a first width, and in an area other than the connection overlapping region, the protrusion has a second width, wherein the first width is less than the second width, and the first width and the second width are dimensions along an extension direction of the groove.

In another exemplary embodiment, a surface of the protrusion in the connection overlapping region has a first roughness, and a surface of the protrusion in the area other than the connection overlapping region has a second roughness, wherein the first roughness is greater than the second roughness.

In an exemplary embodiment, the driving circuit layer may include multiple circuit units constituting multiple rows of units and multiple columns of units, the multiple circuit units are arranged in alignment in the rows of units and the multiple circuit units are arranged in alignment in the columns of units. The light emitting structure layer includes multiple sub-pixels constituting multiple rows of pixels and multiple columns of pixels, the multiple sub-pixels are arranged in alignment in the rows of pixels and the multiple sub-pixels are arranged in a staggered manner in the columns of pixels.

In an exemplary embodiment, at least one circuit unit includes a pixel driving circuit, the pixel driving circuit is connected to a first scan signal line, a second scan signal line and a light emitting control line respectively. The pixel driving circuit at least includes a storage capacitor, in the M-th row of units, the first scan signal line is located at one side of the storage capacitor close to the (M+1)-th row of units, the second scan signal line is located at one side of the storage capacitor away from the (M+1)-th row of units, and the light emitting control line is located between the storage capacitor and the second scan signal line. At least one sub-pixel includes an anode connected to the pixel driving circuit, the anode in the (2M−1)-th row of pixels is located at one side of the light emitting control line in the M-th row of units away from the (M+1)-th row of units, the anode in the 2M-th row of pixels is located at one side of the light emitting control line in the M-th row of units close to the (M+1)-th row of units, with 1≤M≤K, and K being the number of rows of units.

In an exemplary embodiment, an orthographic projection of the anode in the (2M−1)-th row of pixels on the base substrate overlaps at least partially with an orthographic projection of the second scan signal line in the M-th row of units on the base substrate, and an orthographic projection of the anode in the 2M-th row of pixels on the base substrate overlaps at least partially with an orthographic projection of the storage capacitor on the base substrate.

In an exemplary embodiment, the orthographic projection of the anode in the (2M−1)-th row of pixels on the base substrate overlaps at least partially with an orthographic projection of two pixel driving circuits in the M-th row of units on the base substrate, and the orthographic projection of the anode in the 2M-th row of pixels on the base substrate overlaps at least partially with an orthographic projection of two pixel driving circuits in the M-th row of units on the base substrate.

In an exemplary embodiment, at least one photo spacer is located between adjacent anodes in a row of pixels, or at least one photo spacer is located between adjacent anodes in a column of pixels.

In an exemplary embodiment, at least one photo spacer is located between the anode in the (2M−1)-th row of pixels and the anode in the 2M-th row of pixels.

In an exemplary embodiment, an orthographic projection of a photo spacer located between the anode in the (2M−1)-th row of pixels and the anode in the 2M-th row of pixels on the base substrate overlaps at least partially with an orthographic projection of the light emitting control line in the M-th row of units on the base substrate.

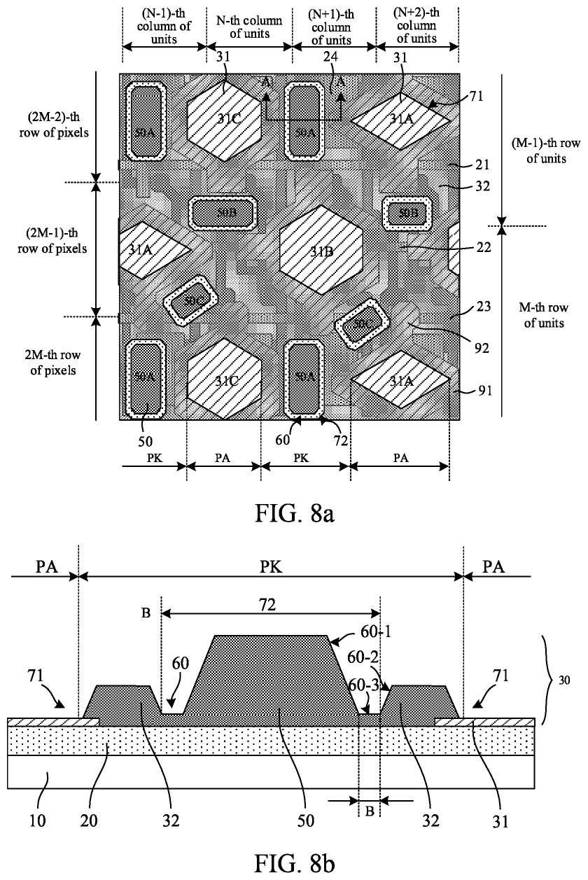

FIG. 8a is a schematic diagram of a planar structure of a sub-pixel in accordance with an exemplary example of the present disclosure, which illustrates a structure of an anode, a pixel opening and a photo spacer. FIG. 8b is a sectional view taken along an A-A direction in FIG. 8a. As shown in FIGS. 8a and 8b, in a plane parallel to the display substrate, the display substrate may at least include multiple pixel light emitting regions PA and pixel spacer regions PK located between adjacent pixel light emitting regions PA.

In an exemplary embodiment, in a plane perpendicular to the display substrate, the display substrate may include a driving circuit layer 20 disposed on a base substrate 10 and a light emitting structure layer 30 disposed on one side of the driving circuit layer 20 away from the base substrate. The light emitting structure layer 30 may at least include an anode 31, a pixel definition layer 32 and at least one photo spacer 50. The anode 31 may be disposed on one side of the driving circuit layer 20 away from the base substrate 10, and the pixel definition layer 32 may be disposed on one side of the anode 31 away from the base substrate 10. A pixel opening 71 and a spacer opening 72 may be provided in the pixel definition layer 32. The pixel opening 71 exposes a surface of the anode 31, and the spacer opening 72 forms a pixel light emitting region PA and a pixel spacer region PK located between adjacent pixel light emitting regions PA. The spacer opening 72 may be provided in the pixel spacer region PK, the photo spacer 50 is provided in the spacer opening 72, and an orthographic projection of the photo spacer 50 on the base substrate is within a range of an orthographic projection of the spacer opening 72 on the base substrate.

In an exemplary embodiment, an area of the orthographic projection of the photo spacer 50 on the base substrate is less than an area of the orthographic projection of the spacer opening 72 on the base substrate. A groove 60 is formed between the photo spacer 50 and the spacer opening 72. Forming the groove 60 between the photo spacer 50 and the spacer opening 72 means that a gap is formed between an outer sidewall of the photo spacer 50 and an inner sidewall of the spacer opening 72. A first sidewall 60-1 of the gap is the outer sidewall of the photo spacer 50, a second sidewall 60-2 of the gap is the inner sidewall of the spacing opening 72, and the bottom wall 60-3 of the gap is connected to the first sidewall 60-1 and the second sidewall 60-2, respectively. A distance between a surface of the bottom wall 60-3 and the base substrate is not only less than a distance between a surface of the photo spacer 50 away from the base substrate and the base substrate, but also less than a distance between a surface of the pixel definition layer 32 away from the base substrate and the base substrate.

In an exemplary embodiment, in the plane perpendicular to the display substrate, a transverse distance between the outer sidewall (first sidewall 60-1) of the photo spacer 50 and the inner sidewall (second sidewall 60-2) of the spacer opening 72 gradually increases along a direction away from the base substrate 10, and the transverse distance is a dimension in the plane parallel to the display substrate.

In an exemplary embodiment, a width B of a surface of the groove 60 close to the base substrate may be about 1 μm to 2 μm, the surface of the groove 60 close to the base substrate may be the bottom wall 60-3, and the width B may be a dimension perpendicular to an extension direction of the groove. For example, the width B may be about 1.0 μm, or the width B may be about 1.5 μm.

In an exemplary embodiment, the distance between the surface of the photo spacer 50 away from the base substrate and the base substrate is greater than the distance between the surface of the pixel definition layer 32 away from the base substrate and the base substrate.

In an exemplary embodiment, in a plane parallel to the base substrate, the pixel opening 71 may be in a shape of any one or more of a triangle, a rectangle, a pentagon, a hexagon, a circle and an ellipse, the spacer opening 72 may be in a shape of any one or more of a triangle, a rectangle, a pentagon, a hexagon, a circle and an ellipse, and the photo spacer 50 may be in a shape of any one or more of a triangle, a rectangle, a pentagon, a hexagon, a circle and an ellipse.

In an exemplary embodiment, in a plane perpendicular to the base substrate, a cross section of the pixel opening 71 may be in a shape of an inverted trapezoid or an inverted-trapezoid-like shape, a sidewall of which may be in a shape of a straight line, a fold line or a curve.

In an exemplary embodiment, in a plane perpendicular to the base substrate, a cross section of the spacer opening 72 may be in a shape of an inverted trapezoid or an inverted-trapezoid-like shape, a sidewall of which may be in a shape of a straight line, a fold line or a curve.

In an exemplary embodiment, in a plane perpendicular to the base substrate, a cross section of the photo spacer 50 may be in a shape of a regular trapezoid or a regular-trapezoid-like shape, a sidewall of which may be in a shape of a straight line, a fold line or a curve. For example, the cross section of the photo spacer 50 may be in the shape of a round crown or a semi-circle.

In an exemplary embodiment, the shape, size and position of the photo spacer 50 are designed such that the spacer opening 72 and the photo spacer 50 are provided at a position in the pixel spacer region PK, which can avoid the anode 31 as much as possible, such that there is no overlap between the orthographic projection of the spacer opening 72 on the base substrate and the orthographic projection of the anode 31 on the base substrate, or there is no overlap between the orthographic projection of the photo spacer 50 on the base substrate and the orthographic projection of the anode 31 on the base substrate, or there is no overlap between the orthographic projection of the groove 60 on the base substrate and the orthographic projection of the anode 31 on the base substrate.

In an exemplary embodiment, at least one anode 31 may include a body portion 91 and at least one protrusion 92. The body portion 91 may be in a shape of any one or more of a triangle, a rectangle, a pentagon, a hexagon, a circle and an ellipse, and a protrusion 92 may be in a shape of a strip. A first end of the protrusion 92 is connected to the body portion 91, and a second end of the protrusion 92 extends in a direction away from the body portion 91.

In the exemplary embodiment, a position of the pixel opening 71 corresponds to a position of the body portion 91 of the anode 31. The pixel opening 71 exposing the surface of the anode 31 means that the pixel opening 71 exposes a surface of the body portion 91 of the anode 31.

In an exemplary embodiment, there being no overlap between the orthographic projection of the spacer opening 72 on the base substrate and the orthographic projection of the anode 31 on the base substrate means that there is no overlap between the orthographic projection of the spacer opening 72 on the base substrate and an orthographic projection of the protrusion 92 of the anode 31 on the base substrate. There being no overlap between the orthographic projection of the photo spacer 50 on the base substrate and the orthographic projection of the anode 31 on the base substrate means that there is no overlap between the orthographic projection of the photo spacer 50 on the base substrate and the orthographic projection of the protrusion 92 of the anode 31 on the base substrate. There being no overlap between the orthographic projection of the groove 60 on the base substrate and the orthographic projection of the anode 31 on the base substrate means that there is no overlap between the orthographic projection of the groove 60 on the base substrate and the orthographic projection of the protrusion 92 of the anode 31 on the base substrate.

In an exemplary embodiment, the driving circuit layer 20 may include multiple circuit units, at least one of the circuit units may include a pixel driving circuit which may be connected to multiple signal lines. In an exemplary embodiment, the multiple signal lines may at least include a first scan signal line 21, a second scan signal line 22 and a light emitting control line 23 extending along the horizontal direction. The pixel driving circuit may at least include a storage capacitor which may at least include a first plate 24 and multiple transistors which may at least include a third transistor serving as a driving transistor. The first plate 24 may serve as a gate electrode of the third transistor.

In an exemplary embodiment, the anode 31 may include a first anode 31A of a red sub-pixel, a second anode 31B of a blue sub-pixel and a third anode 31C of a green sub-pixel. The first anode 31A, the second anode 31B and the third anode 31C may each include a body portion and at least one protrusion. Shapes of the body portions of the first anode 31A, the second anode 31B and the third anode 31C may be different, and connection positions and shapes of the protrusions of the first anode 31A, the second anode 31B and the third anode 31C may be different.

In an exemplary embodiment, because the circuit units of the driving circuit layer 20 are arranged in alignment, the sub-pixels of the light emitting circuit layer 30 are in a triangle-like arrangement, positions and shapes of the circuit units do not correspond to positions and shapes of the sub-pixels, that is, the positions and shapes of the pixel driving circuits do not correspond to positions and shapes of the anodes to which the pixel driving circuits are connected, and two rows of pixels of the light emitting circuit layer 30 correspond to one row of units of the driving circuit layer 20.

In an exemplary embodiment, in the (2M−1)-th row of pixels, the body portion of the first anode 31A, the body portion of the second anode 31B and the body portion of the third anode 31C may be located at one side of the light emitting control line 23 in the M-th row of units away from the (M+1)-th row of units. In the 2M-th row of pixels, the body portion of the first anode 31A, the body portion of the second anode 31B and the body portion of the third anode 31C may be located at one side of the light emitting control line 23 in the M-th row of units close to the (M+1)-th row of units.

In an exemplary embodiment, an orthographic projection of each of the body portion of the first anode 31A, the body portion of the second anode 31B and the body portion of the third anode 31C in the (2M−1)-th row of pixels on the base substrate overlaps at least partially with an orthographic projection of the second scan signal line 22 in the M-th row of units on the base substrate.

In an exemplary embodiment, an orthographic projections of each of the body portion of the first anode 31A, the body portion of the second anode 31B and the body portion of the third anode 31C in the 2M-th row of pixels on the base substrate overlap at least partially with an orthographic projection of the first plate 24 in the M-th row of units on the base substrate.

In an exemplary embodiment, a width of the body portion of the first anode 31A, the body portion of the second anode 31B and the body portion of the third anode 31C may be greater than the width of one circuit unit, the width being a dimension in the horizontal direction.

In an exemplary embodiment, an orthographic projection of the anode in the (2M−1)-th row of pixels on the base substrate overlaps at least partially with an orthographic projection of two pixel driving circuits in the M-th row of units on the base substrate, and an orthographic projection of the anodes in the 2M-th row of pixels on the base substrate overlaps at least partially with the orthographic projection of the two pixel driving circuits in the M-th row of units on the base substrate.

In an exemplary embodiment, in the (2M−1)-th row of pixels, the orthographic projection of the body portion of the first anode 31A on the base substrate overlaps at least partially with not only an orthographic projection of the pixel driving circuit in the N-th column of units on the base substrate, but also with an orthographic projection of the pixel driving circuit in the (N+1)-th column of units on the base substrate. In the 2M-th row of pixels, the orthographic projection of the body portion of the second anode 31B on the base substrate overlaps at least partially with not only the orthographic projection of the pixel driving circuit in the N-th column of units on the base substrate, but also with an orthographic projection of the pixel driving circuit in the (N−1)-th column of units on the base substrate. The orthographic projection of the body portion of the third anode 31C on the base substrate overlaps at least partially with not only the orthographic projection of the pixel driving circuit in the (N+1)-th column of units on the base substrate, but also with an orthographic projection of the pixel driving circuit in the (N+2)-th column of units on the base substrate.

In an exemplary embodiment, the photo spacers 50 may be in a shape of a rectangle, corners of which may be set to be chamfers. The rectangle includes two diametrically opposite long sides and two diametrically opposite short sides.

In an exemplary embodiment, the photo spacers 50 may at least include a first photo spacer 50A with long sides extending along the direction of the columns of pixels, a second photo spacer 50B with long sides extending along the direction of the rows of pixels, and a third photo spacer 50C with long sides extending along an oblique direction. There is a first included angle between the oblique direction and the direction of the columns of pixels, or there is a second included angle between the oblique direction and the direction of the rows of pixels, with the first included angle and the second included angle being greater than 0° and less than 90°

In an exemplary embodiment, at least one photo spacer 50 may be disposed between adjacent anodes 31, so that there is no overlap between the orthographic projection of the spacer opening 72 on the base substrate and the orthographic projection of the anodes 31 on the base substrate, or there is no overlap between the orthographic projection of the at least one photo spacer 50 on the base substrate and the orthographic projection of the anodes 31 on the base substrate, or there is no overlap between the orthographic projection of the groove 60 on the base substrate and the orthographic projection of the anodes 31 on the base substrate.

In an exemplary embodiment, at least one photo spacer 50 being disposed between adjacent anodes 31 may include any one or more of the following cases that: a first photo spacer 50A may be disposed between adjacent anodes 31 in one row of pixels, a second photo spacer 50B may be disposed between adjacent anodes 31 in one column of pixels, and a third photo spacer 50C may be disposed between an anode in the (2M−1)-th row of pixels and an anode in the (2M−1)-th row of pixels, and the anode in the (2M−1)-th row of pixels is adjacent to the anode in the (2M−1)-th row of pixels.

In an exemplary embodiment, an orthographic projection of the third photo spacer 50C on the base substrate overlaps at least partially with an orthographic projection of the light emitting control line on the base substrate.

In an exemplary embodiment, multiple photo spacers 50 may constitute multiple rows of photo spacers and multiple columns of photo spacers. Multiple photo spacers 50 sequentially arranged along the horizontal direction may be referred to as a row of photo spacers, and multiple photo spacers 50 sequentially arranged along the vertical direction may be referred to as a column of photo spacers. The multiple rows of photo spacers and the multiple columns of photo spacers constitute an array of photo spacers regularly arranged.

In an exemplary embodiment, in at least one row of pixels, the number of photo spacers is greater than the number of anodes. For example, not only multiple first photo spacers 50A but also multiple third photo spacers 50C are included in the 2M-th row of pixels.

In an exemplary embodiment, three rows of pixels correspond to four rows of photo spacers, i.e., four rows of photo spacers are provided in an area where the three rows of pixels are located. For example, two rows of photo spacers including multiple first photo spacers 50A, one row of photo spacers including multiple second photo spacers 50B and one row of photo spacers including multiple third photo spacers 50C are provided in an area where the (2M−2)-th row of pixels, the (2M−1)-th row of pixels and the (2M−1)-th row of pixels are located.

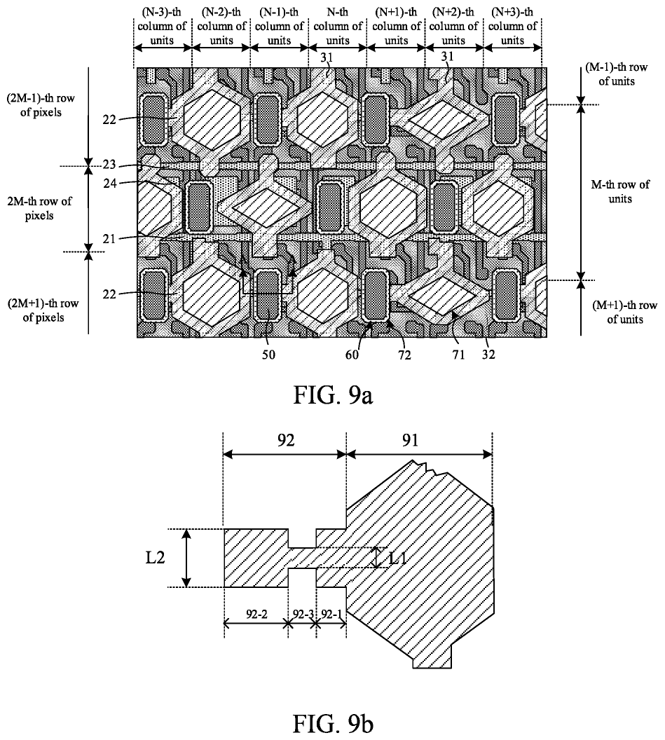

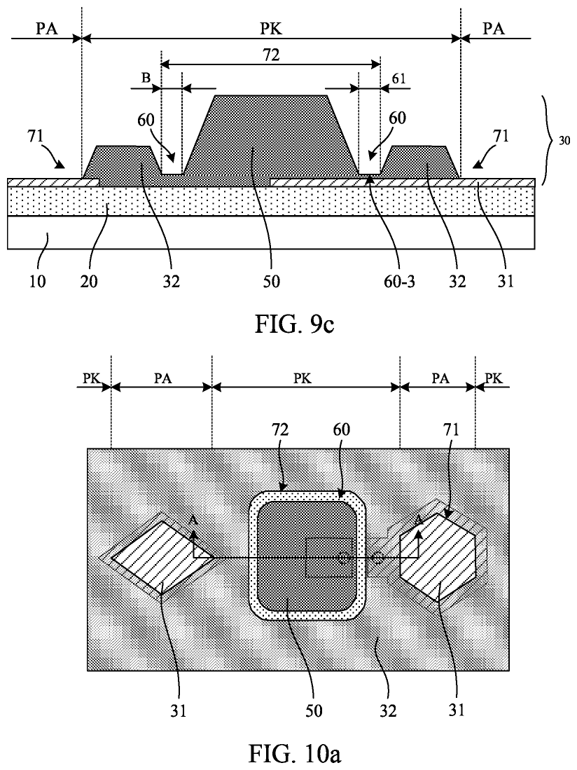

FIG. 9a is a schematic diagram of a planar structure of another sub-pixel in accordance with an exemplary example of the present disclosure, which illustrates a structure of an anode, a pixel opening and a photo spacer. FIG. 9b is a schematic diagram of a planar structure of one anode in FIG. 9a, and FIG. 9c is a sectional view taken along an A-A direction in FIG. 9a. As shown in FIGS. 9a to 9c, a pixel opening 71 may be provided in the pixel definition layer 32 in a pixel light emitting region, and the pixel definition layer within the pixel opening 71 is removed to expose a surface of the anode 31. At least one spacer opening 72 may be provided in the pixel definition layer 32 in a pixel spacer region. A photo spacer 50 is disposed within the spacer opening 72. An orthographic projection of the photo spacer 50 on a base substrate may be within a range of an orthographic projection of the spacer opening 72 on the base substrate. An annular groove 60 surrounding the entire photo spacer 50 is formed between the photo spacer 50 and the spacer opening 72.

In an exemplary embodiment, a width B of a surface of the groove 60 close to the base substrate may be about 1 μm to 2 μm. The width B may be a dimension perpendicular to an extension direction of the groove. For example, the width B may be about 1.0 μm, or the width B may be about 1.5 μm.

In an exemplary embodiment, the anode 31 may be disposed on one side of the driving circuit layer 20 away from the base substrate. At least one anode 31 may include a body portion 91 and at least one protrusion 92. The body portion 91 may be in a shape of any one or more of a triangle, a rectangle, a pentagon, a hexagon, a circle and an ellipse, and the at least one protrusion 92 may be in a shape of a strip. A first end of each protrusion 92 is connected to the body portion 91, and a second end of the protrusion 92 extends to the pixel spacer region PK in the direction away from the body portion 91. In an exemplary embodiment, the protrusion 92 is configured to be connected to a pixel driving circuit of the driving circuit layer 20. In another exemplary embodiment, the protrusion 92 may be configured to block a corresponding transistor to prevent illumination from affecting electrical properties of the transistor. In another exemplary embodiment, the protrusion 92 may be configured to form a corresponding parasitic capacitance.

In an exemplary embodiment, the orthographic projection of the spacer opening 72 on the base substrate overlaps at least partially with an orthographic projection of the protrusion 92 of the anode 31 on the base substrate, and the orthographic projection of the photo spacer 50 on the base substrate overlaps at least partially with the orthographic projection of the protrusion 92 of the anode 31 on the base substrate.

In an exemplary embodiment, an orthographic projection of the groove 60 on the base substrate overlaps at least partially with the orthographic projection of the protrusion 92 of the anode 31 on the base substrate to form a connection overlapping region 61.

In an exemplary embodiment, in an area where the connection overlapping region 61 is located, a distance between a surface of the bottom wall 60-3 of the groove 60 and the base substrate is greater than a distance between a surface of the protrusion 92 of the anode 31 away from the base substrate and the base substrate, i.e., the bottom wall 60-3 of the groove 60 overlays the surface of the protrusion 92.

In an exemplary embodiment, the protrusion 92 may have a first width L1 in the area where the connection overlapping region 61 is located, and the protrusion 92 may have a second width L2 in an area other than the connection overlapping region 61. The first width L1 may be less than the second width L2, and the first width L1 and the second width L2 may be dimensions along the extension direction of the annular groove 60.

In an exemplary embodiment, at least one strip-shaped protrusion 92 may include a first protrusion 92-1, a second protrusion 92-2 and a third protrusion 92-3. A first end of each first protrusion 92-1 is connected to the body portion 91, a second end of the first protrusion 92-1 is connected to a first end of the third protrusion 92-3 after extending in the direction away from the body portion 91, a second end of the third protrusion 92-3 is connected to a first end of the second protrusion 92-2 after extending in the direction away from the body portion 91, and a second end of the second protrusion 92-2 extends in the direction away from the body portion 91.

In an exemplary embodiment, an orthographic projection of the second projection 92-2 on the base substrate overlaps at least partially with the orthographic projection of the photo spacer 50 on the base substrate, there is no overlap between orthographic projections of the first protrusion 92-1 and the second protrusion 92-2 on the base substrate and the orthographic projection of the groove 60 on the base substrate, and an orthographic projection of the third protrusion 92-3 on the base substrate overlaps at least partially with the orthographic projection of the groove 60 on the base substrate. The third protrusion 92-3 has the first width L1, and the first protrusion 92-1 or the second protrusion 92-2 has the second width L2, such that the width of the protrusion in the connection overlapping region 61 is less than the width of the protrusion in the area other than the connection overlapping region 61.

In an exemplary embodiment, the first width L1 may be about ¼ to 1/20 of the second width L2.

In an exemplary embodiment, the second width L1 may be about 0.5 μm to 2 μm. For example, the first width L1 may be about 1 μm.

In an exemplary embodiment, the second width L2 may be about 8 μm to 12 μm. For example, the second width L2 may be about 10 μm.

In other exemplary embodiments, a width of the first protrusion 92-1 may be the same as that of the third protrusion 92-3, or a width of the second protrusion 92-2 may be the same as that of the third protrusion 92-3, or the widths of both the first protrusion 92-1 and the second protrusion 92-2 may be the same as that of the third protrusion 92-3, i.e., the protrusion 92 is an equal-width structure having the first width L1, and the present disclosure is not limited thereto.

In an exemplary embodiment, body portions of multiple anodes 31 in the (2M−1)-th row of pixels may be located at one side of the light emitting control line 23 in the M-th row of units away from the (M+1)-th row of units. Body portions of multiple anodes 31 in the 2M-th row of pixels may be located at one side of the light emitting control line 23 in the M-th row of units close to the (M+1)-th row of units.

In an exemplary embodiment, orthographic projections of the body portions of the multiple anodes 31 in the (2M−1)-th row of pixels on the base substrate overlap at least partially with an orthographic projection of the second scan signal line 22 in the M-row of units on the base substrate.

Orthographic projections of the body portions of the multiple anodes 31 on the base substrate in the 2M-th row of pixels on the base substrate overlap at least partially with an orthographic projection of a first plate 24 in the M-row of units on the base substrate.

In an exemplary embodiment, a width of the body portion of at least one anode 31 may be greater than a width of one circuit unit. An orthographic projection of the body portion of the at least one anode 31 in the (2M−1)-th row of pixels on the base substrate overlaps at least partially with orthographic projections of pixel driving circuits in two columns of units on the base substrate.

In an exemplary embodiment, at least one photo spacer 50 being disposed between adjacent anodes 31 includes any one or more of the following cases that: the at least one photo spacer 50 may be disposed between adjacent anodes 31 in a row of pixels, and the at least one photo spacer 50 may be disposed between adjacent anodes 31 in a column of pixels.

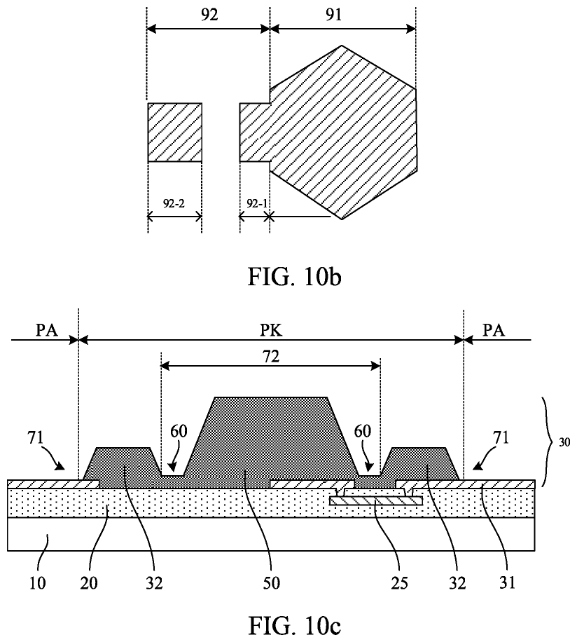

FIG. 10a is a schematic diagram of a planar structure of another sub-pixel in accordance with an exemplary example of the present disclosure, which illustrates another position relationship between an anode, a pixel opening and a photo spacer. FIG. 10b is a schematic diagram of a planar structure of one anode in FIG. 10a, and FIG. 10c is a sectional view taken along an A-A direction in FIG. 10a. Structures of the pixel definition layer and the photo spacer in the present exemplary example are substantially the same as the structures in the foregoing examples, and a difference is that the orthographic projection of the photo spacer 50 on the base substrate overlaps at least partially with the orthographic projection of the protrusion 92 of the anode 31 on the base substrate, but there is no overlap between the orthographic projection of the groove 60 on the base substrate and the orthographic projection of the protrusion 92 of the anode 31 on the base substrate.

As shown in FIGS. 10a to 10c, in an exemplary embodiment, the protrusion 92 may include a first protrusion 92-1 and a second protrusion 92-2 disposed at intervals. A first end of the first protrusion 92-1 is connected to the body portion 91 and a second end of the first protrusion 92-1 extends in the direction away from the body portion 91. A first end of the second protrusion 92-2 is disposed on one side of the first protrusion 92-1 away from the body portion 91, and a second end of the second protrusion 92-2 extends in the direction away from the body portion 91. An orthographic projection of the second protrusion 92-2 on the base substrate overlaps at least partially with the orthographic projection of the photo spacer 50 on the base substrate, and there is no overlap between orthographic projections of the first protrusion 92-1 and the second protrusion 92-2 on the base substrate and the orthographic projection of the groove 60 on the base substrate.

In an exemplary embodiment, a connection electrode 25 is provided in the driving circuit layer 20. An orthographic projection of the connection electrode 25 on the base substrate overlaps at least partially with the orthographic projection of the groove 60 on the base substrate. The second end of the first protrusion 92-1 is connected to a first end of the connection electrode 25 through a via hole, and the first end of the second protrusion 92-2 is connected to a second end of the connection electrode 25 through a via hole. Thus, not only connection between the first protrusion 92-1 and the second protrusion 92-2 through the connection electrode 25 is implemented, but also zero-overlap between the orthographic projection of the protrusion 92 on the base substrate and the orthographic projection of the groove 60 on the base substrate is implemented.

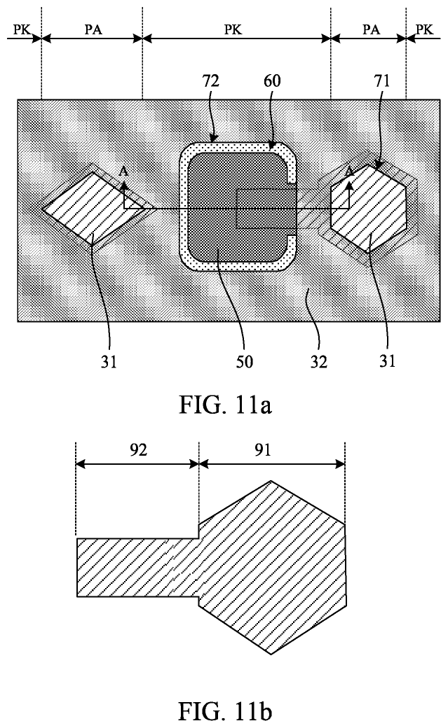

FIG. 11a is a schematic diagram of a planar structure of another sub-pixel in accordance with an exemplary example of the present disclosure, which illustrates another position relationship between an anode, a pixel opening and a photo spacer. FIG. 11b is a schematic diagram of a planar structure of one anode in FIG. 11a, and FIG. 11c is a sectional view taken along an A-A direction in FIG. 11a. Structures of the pixel definition layer and the photo spacer in the present exemplary example are substantially the same as the structures in the foregoing examples, and a difference is that the entire photo spacer 50 is not surrounded by the groove 60 formed between the photo spacer 50 and the spacer opening 72, and the groove 60 is not provided between the photo spacer 50 and the pixel definition layer 32 in an area where the protrusion 92 of the anode 31 is located.

As shown in FIGS. 11a to 11c, in an exemplary embodiment, the protrusion 92 may be in the shape of a strip of equal width, a first end of the protrusion 92 is connected to the body portion 91, and a second end of the protrusion 92 extends to an area where the photo spacer 50 is located in the direction away from the body portion 91, so that the orthographic projection of the protrusion 92 of the anode 31 on the base substrate overlaps at least partially with the orthographic projection of the photo spacer 50 on the base substrate.

In an exemplary embodiment, the groove 60, which may be in a shape of letter “C”, surrounds a portion of the photo spacer 50 and is disposed in an area other than the area where the projection 92 is located. The groove 60 is formed between the photo spacer 50 and the spacer opening 72 in the area other than the area where the projection 92 is located, and the groove 60 is not formed between the photo spacer 50 and the pixel definition layer 32 in the area where the protrusion 92 is located, so that zero-overlap between the orthographic projection of the protrusion 92 on the base substrate and the orthographic projection of the groove 60 on the base substrate is implemented.

In an exemplary embodiment, the protrusion 92 may in a conventional structure with the second width. The width of the protrusion 92 may be about 8 μm to 12 μm.

In another exemplary embodiment, the protrusion 92 may be in an overall narrowed structure with the first width. The width of the protrusion 92 may be about 0.5 μm to 2 μm.

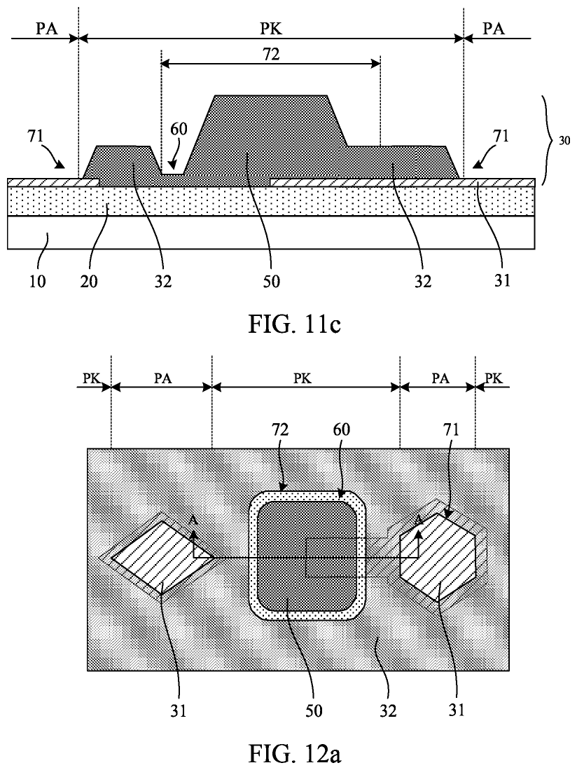

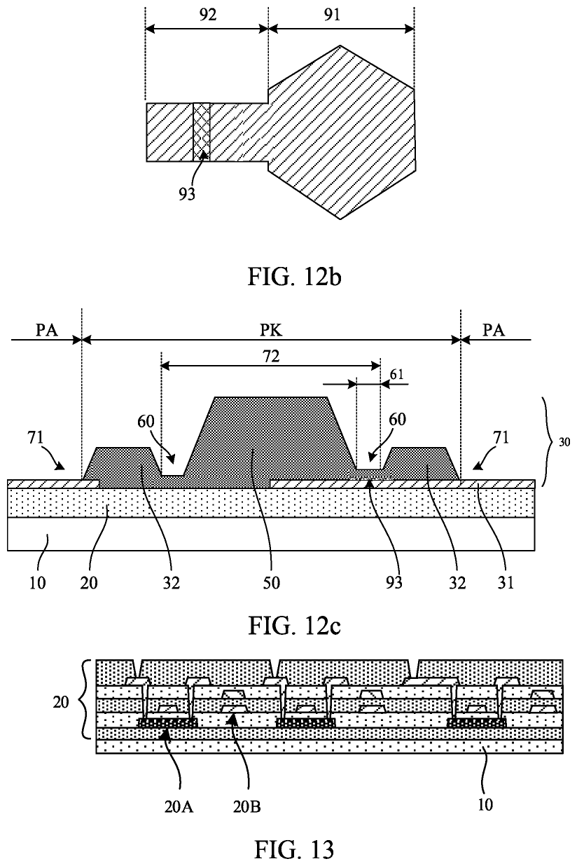

FIG. 12a is a schematic diagram of a planar structure of another sub-pixel in accordance with an exemplary example of the present disclosure, which illustrates another position relationship between an anode, a pixel opening and a photo spacer. FIG. 12b is a schematic diagram of a planar structure of the anode in FIG. 12a, and FIG. 11c is a sectional view taken along an A-A direction in FIG. 12a. Structures of the pixel definition layer and the photo spacer in the present exemplary example are substantially the same as the structures in the foregoing examples, and a difference is that the annular groove 60 surrounding the entire photo spacer 50 is formed between the photo spacer 50 and the spacer opening 72, and the orthographic projection of the groove 60 on the base substrate overlaps at least partially with the orthographic projection of the protrusion 92 of the anode 31 on the base substrate to forming the connection overlapping region 61. The protrusion 92 in the area where the connection overlapping region 61 is located has a rough surface.

As shown in FIGS. 12a to 12c, in an exemplary embodiment, the protrusion 92 may be in a shape of a strip of equal width, a first end of the protrusion 92 is connected to the body portion 91, and a second end of the protrusion 92 extends to an area where the photo spacer 50 is located in the direction away from the body portion 91, so that the orthographic projection of the protrusion 92 of the anode 31 on the base substrate overlaps at least partially with the orthographic projection of the photo spacer 50 on the base substrate.

In an exemplary embodiment, the protrusion 92 includes at least one rough surface region 93, and the at least one rough surface region 93 may be formed by ion bombardment on a surface of the protrusion 92. A surface of an area where the rough surface region 93 is located has a first roughness, and a surface of an area other than the rough surface region 93 has a second roughness. The first roughness may be greater than the second roughness.

In an exemplary embodiment, an orthographic projection of the rough surface region 93 on the base substrate overlaps at least partially with the orthographic projection of groove 60 on the base substrate.

In an exemplary embodiment, the protrusion 92 may in a conventional structure with the second width. The width of the protrusion 92 may be about 8 μm to 12 μm.

In another exemplary embodiment, the protrusion 92 may be in an overall narrowed structure with the first width. The width of the protrusion 92 may be about 0.5 μm to 2 μm.

A manufacturing process of the display substrate will be described below by way of example. “Patterning processes” mentioned in the present disclosure include photoresist coating, mask exposure, development, etching, photoresist stripping, etc., for metal materials, inorganic materials or transparent conductive materials, and include organic material coating, mask exposure, development, etc., for organic materials. Deposition may be any one or more of sputtering, evaporation and chemical vapor deposition, coating may be any one or more of spray coating, spin coating and inkjet printing, and etching may be any one or more of dry etching and wet etching, the present disclosure is not limited thereto. “Film” refers to a layer of film formed by a certain material on a base substrate using deposition, coating or other processes. If the “film” does not need the patterning processes in the entire manufacturing process, the “film” may also be called a “layer”. If the “film” needs the patterning processes in the entire manufacturing process, the “film” is called a “film” before the patterning processes are performed and is called a “layer” after the patterning processes are performed. A “layer” processed by a patterning process includes at least one “pattern”. “A and B being disposed on a same layer” mentioned in the present disclosure means that A and B are formed simultaneously through the same running of a patterning process, and a “thickness” of a film layer is a dimension of the film layer in a direction perpendicular to the display substrate. In an exemplary example of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A coincides with the boundary of the orthographic projection of B.

In an exemplary embodiment, taking three sub-pixels of the display substrate as an example, a manufacturing process of the display substrate may include the following operations.

(1) A pattern of a driving circuit layer is formed. In an exemplary embodiment, forming the pattern of the driving circuit layer may include following operations.

A first insulating thin film and a semiconductor thin film are sequentially deposited on a base substrate, and the semiconductor thin film is patterned through a patterning process to form a first insulating layer overlaying the entire base substrate and form a pattern of a semiconductor layer disposed on the first insulating layer. The pattern of the semiconductor layer at least includes an active layer in each sub-pixel.

Then, a second insulating thin film and a first metal thin film are sequentially deposited, and the first metal thin film is patterned through a patterning process to form a second insulating layer overlaying the pattern of the semiconductor layer and form a pattern of a first metal layer disposed on the second insulating layer. The pattern of the first metal layer at least includes a gate electrode and a first plate in each sub-pixel.

Then, a third insulating thin film and a second metal thin film are deposited sequentially, and the second metal thin film is patterned through a patterning process to form a third insulating layer overlaying the first metal layer and form a pattern of a second metal layer disposed on the third insulating layer. The pattern of the second metal layer at least includes a second plate located in each sub-pixel. An orthographic projection of the second plate on the base substrate overlaps at least partially with an orthographic projection of the first plate on the base substrate.

Subsequently, a fourth insulating thin film is deposited, and a pattern of a fourth insulating layer overlaying the second metal layer is formed through a patterning process. Multiple first via holes are formed in the fourth insulating layer, and the fourth insulating layer, the third insulating layer and the second insulating layer in the first via holes are etched away to expose two ends of the active layer.

Then, a third metal thin film is deposited, and the third metal thin film is patterned through a patterning process to form a pattern of a third metal layer on the fourth insulating layer. The pattern of the third metal layer at least includes a first electrode and a second electrode in each sub-pixel. The first electrode and the second electrode are respectively connected to the active layer through the first via holes.

Then, a planarization thin film is coated, and the planarization thin film is patterned through a patterning process to form a planarization layer overlaying the third metal layer. Second via holes are formed in the planarization layer, and the planarization thin film in the second via holes is etched away to expose the second electrode in each sub-pixel.

So far, the patterns of the driving circuit layer 20 have been manufactured on the base substrate 10, as illustrated in FIG. 13. In an exemplary embodiment, the driving circuit layer 20 of each sub-pixel may include multiple transistors and a storage capacitor that form a pixel driving circuit. The pixel driving circuit including one transistor 20A and one storage capacitor 20B is illustrated by way of example. In an exemplary embodiment, the transistor 20A may include an active layer, a gate electrode, a first electrode and a second electrode, and the storage capacitor 20B may include a first plate and a second plate.

In an exemplary embodiment, the base substrate may be a rigid base substrate, which may be made of glass or quartz. In some possible implementations, the base substrate may be a flexible base substrate, or may be a silicon wafer. The flexible substrate may be made of a material such as polyimide (PI) or polyethylene terephthalate (PET). The flexible base substrate may be in a single-layer structure, or may be in a stacked structure comprised of an inorganic material layer and a flexible material layer, and the present disclosure is not limited thereto.

In an exemplary embodiment, the first insulating layer, the second insulating layer, the third insulating layer and the fourth insulating layer may be made of any one or more of silicon oxide (SiOx), silicon nitride (SiNx) and silicon oxynitride (SiON), and may be in a single layer, multi-layers or a composite layer. The first insulating layer is referred to as a buffer layer for improving water and oxygen resistance performance of the base substrate, the second insulating layer and the third insulating layer are referred to as gate insulating (GI) layers, and the fourth insulating layer is referred to as an interlayer insulating (ILD) layer. The planarization film may be made of an organic material, such as resin. The first metal layer, the second metal layer and the third metal layer may be made of metal materials, such as any one or more of silver (Ag), copper (Cu), aluminum (Al), titanium (Ti) and molybdenum (Mo), or an alloy material of the aforementioned metals, such as aluminum neodymium alloy (AlNd) or molybdenum niobium alloy (MoNb), and may be in a single-layer structure or a multi-layered composite structure, such as Ti/Al/Ti, etc. The semiconductor layer may be made of various materials, such as amorphous indium gallium zinc oxide (a-IGZO), zinc oxynitride (ZnON), indium zinc tin oxide (IZTO), amorphous silicon (a-Si), polycrystalline silicon (p-Si), sexithiophene and polythiophene, that is, the present disclosure is applicable to transistors manufactured based on oxide technology, silicon technology and organic matter technology.

In an exemplary embodiment, the driving circuit layer 20 may further include a power supply line, a connection electrode and a fifth insulating (PVX) layer, etc., the present disclosure is not limited thereto.

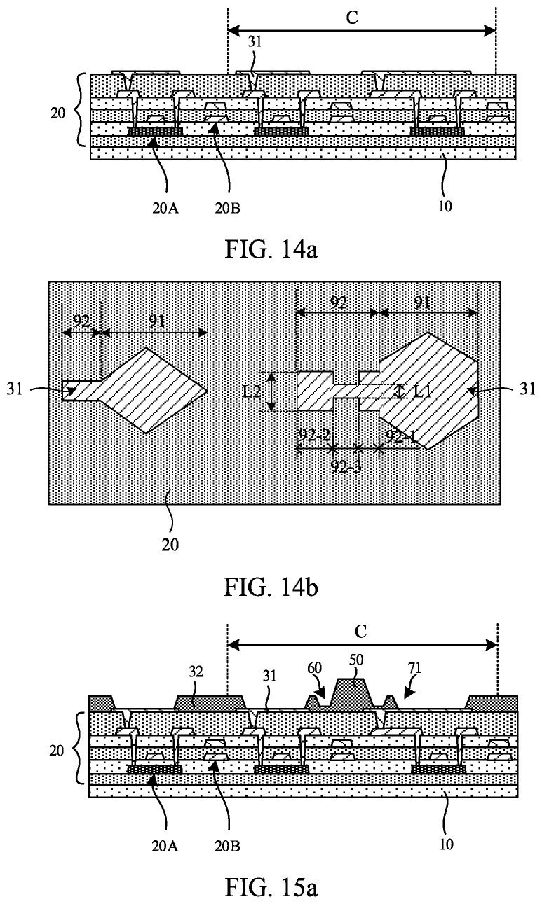

(2) A pattern of an anode conductive layer is formed. In an exemplary embodiment, forming the pattern of the anode conductive layer may include: depositing an anode conductive thin film on the base substrate on which the aforementioned patterns are formed, and patterning the anode conductive thin film through a patterning process to form a pattern of an anode conductive layer. The pattern of the anode conductive layer at least includes an anode 31 in each sub-pixel. The anode 31 is connected to the second electrode of the transistor through the second via hole, as shown in FIGS. 14a and 14b. FIG. 14b is a schematic plan view of an area C in FIG. 14a.

In an exemplary embodiment, the anode conductive layer may be made of a metal material or a transparent conductive material. The metal material may include any one or more of silver (Ag), copper (Cu), aluminum (Al), titanium (TI) and molybdenum (Mo), or an alloy material of the aforementioned metals, and the transparent conductive material may include indium tin oxide (ITO) or indium zinc oxide (IZO). In an exemplary embodiment, the anode conductive layer may be in a single-layer structure or a multi-layer composite structure, such as ITO/Al/ITO.

In an exemplary embodiment, at least one anode 31 may include a body portion 91 and at least one protrusion 92 connected to each other. The body portion 91 may be in a shape of any one or more of a triangle, a rectangle, a rhombus, a pentagon and a hexagon, and the at least one protrusion 92 may be in a shape of a strip. A first end of the protrusion 92 is connected to the body portion 91, and a second end of the protrusion 92 extends in a direction away from the body portion 91. The protrusion 92 may be configured to be connected to the second electrode of the transistor 20A in the pixel driving circuit through the second via hole. In an exemplary embodiment, the protrusion 92 may be configured to block a corresponding transistor to prevent illumination from affecting electrical properties of the transistor. In another exemplary embodiment, the protrusion 92 may be configured to form a corresponding parasitic capacitance.

In an exemplary embodiment, the strip-shaped protrusion 92 may include a first protrusion 92-1, a second protrusion 92-2 and a third protrusion 92-3. A first end of the first protrusion 92-1 is connected to the body portion 91, a second end of the first protrusion 92-1 is connected to a first end of the third protrusion 92-3 after extending in the direction away from the body portion 91, a second end of the third protrusion 92-3 is connected to a first end of the second protrusion 92-2 after extending in the direction away from the body portion 91, and a second end of the second protrusion 92-2 extends towards in direction away from the body portion 91.

In an exemplary embodiment, the third protrusion 92-3 has a first width L1, and the first protrusion 92-1 or the second protrusion 92-2 has a second width L2. The first width L1 may be less than the second width L2.

In an exemplary embodiment, the first width L1 may be about ¼ to 1/20 of the second width L2.

In an exemplary embodiment, the first width L1 may be about 0.5 μm to 2 μm, and the second width L2 may be about 8 μm to 12 μm. For example, the first width L1 may be about 1 μm, and the second width L2 may be about 10 μm.

In an exemplary embodiment, a position of the third protrusion 92-3 corresponds to a position of the subsequently formed groove, that is, an orthographic projection of the third protrusion 92-3 on the base substrate overlaps at least partially with an orthographic projection of a subsequently formed groove on the base substrate. The third protrusion 92-3 is configured to reduce reflection of exposure light off the protrusion and decrease an exposure degree of a pixel definition thin film in an area where the groove is located.

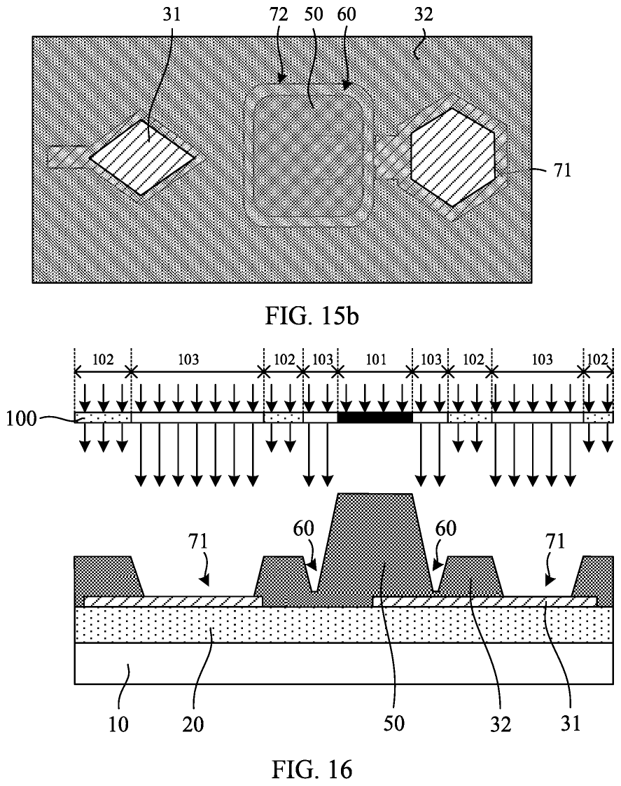

(3) Patterns of a first pixel definition layer and a photo spacer are formed. In an exemplary embodiment, forming the patterns of the pixel define layer and the photo spacer may include: coating a pixel definition thin film on the base substrate on which the aforementioned patterns are formed, and patterning the pixel definition thin film through a patterning process such as halftone mask to form patterns of the pixel definition layer 32 and the photo spacer 50, as shown in FIGS. 15a and 15b. FIG. 15b is a schematic plan view of an area C in FIG. 15a.

In an exemplary embodiment, the pattern of the pixel definition layer 32 may include multiple pixel openings 71 and a spacing opening 72 located between adjacent pixel openings 71. The pixel definition layer of full thickness within the pixel openings 71 is removed to expose a surface of the anode 31. The pixel definition layer of partial thickness within the spacing opening 72 between the adjacent pixel openings 71 is removed to retain the pixel definition layer of partial thickness.

In an exemplary embodiment, the photo spacer 50 is provided in the spacer opening 72. An orthographic projection of the photo spacer 50 on the base substrate may be within a range of an orthographic projection of the spacer opening 72 on the base substrate. An annular groove 60 surrounding the photo spacer 50 is formed between a sidewall of the photo spacer 50 and the spacer opening 72.

In an exemplary embodiment, a height of the photo spacer 50 is greater than a height of the pixel definition layer 32, i.e., a distance between a surface of the photo spacer 50 away from the base substrate and the base substrate is greater than a distance between a surface of the pixel definition layer 32 away from the base substrate and the base substrate.

In an exemplary embodiment, an orthographic projection of the groove 60 on the base substrate overlaps at least partially with an orthographic projection of the third protrusion 92-3 on the base substrate to form a connection overlapping region, and there is no overlap between an orthographic projection of the first protrusion 92-1 and the second protrusion 92-2 on the base substrate and an orthographic projection of the groove 60 on the base substrate.

In an exemplary embodiment, in an area where the connection overlapping region is located, a distance between a surface of a bottom wall of the groove 60 and the base substrate is greater than a distance between a surface of the third protrusion 92-3 away from the base substrate and the base substrate, and the bottom wall of the groove 60 overlays the third protrusion 92-3, that is, the third protrusion 92-3 is not exposed in the groove 60.

In an exemplary embodiment, a width of the groove 60 may be about 1 μm to 2 μm. The width may be a dimension perpendicular to an extension direction of the groove. For example, the width of the groove 60 may be about 1.0 μm, or the width of the groove 60 may be about 1.5 μm.

FIG. 16 is a schematic diagram of an exposure mode in accordance with an exemplary example of the present disclosure. As shown in FIG. 16, in an exemplary embodiment, a halftone mask 100 used for exposure may at least include a non-exposure area 101, a partial exposure area 102 and a full exposure area 103. The exposure mode may be referred to as HPDL mask exposure. Exposure light is not transmitted through the non-exposure area 101 so as not to expose the pixel definition thin film corresponding to this area. A portion of the exposure light is transmitted through the partial exposure area 102 so as to expose the pixel definition thin film of partial thickness corresponding to this area. The exposure light is transmitted completely through the full exposure area 103 so as to fully expose the pixel definition thin film corresponding to this area.

In an exemplary embodiment, the non-exposure area 101 corresponds to an area where the photo spacer 50 is located, the partial exposure area 102 corresponds to an area where the pixel definition layer 32 is located, and the full exposure area 103 corresponds to an area where the pixel openings 71 and groove 60 are located.

In an exemplary embodiment, after the pixel definition thin film corresponding to the non-exposure area 101 is developed and cured, the pixel definition thin film of full thickness is completely retained to form the pattern of the photo spacer 50.

In an exemplary embodiment, after the pixel definition thin film corresponding to the partial exposure area 102 is developed and cured, the pixel definition thin film of partial thickness is retained to form the pattern of the pixel definition layer 32.

In an exemplary embodiment, the pixel definition thin film corresponding to the full exposure area 103 may include a strong exposure area and a weak exposure area. For an area in which an orthographic projection of the full exposure area 103 on the base substrate overlaps with an orthographic projection of the body portion 91 of the anode 31 on the base substrate, because reflection of the exposure light off the body portion 91 increases the exposure degree of this area, this area is a strong exposure area. The pixel definition thin film in this area is removed completely after it is developed and cured, to form the patterns of the pixel openings 71. The pixel openings 71 expose a surface of the body portion 91. For an area in which the orthographic projection of the full exposure area 103 on the base substrate overlaps with the orthographic projection of the third protrusion 92-3 of the anode 31 on the base substrate, because a width of the third protrusion 92-3 is smaller and reflection of the exposure light off the third protrusion 92-3 is less, this area is a weak exposure area. The pixel definition thin film of partial thickness is retained in this area after it is developed and cured, and the bottom wall of the formed groove 60 overlays the third protrusion 92-3, that is, the third protrusion 92-3 is not exposed in the groove 60.

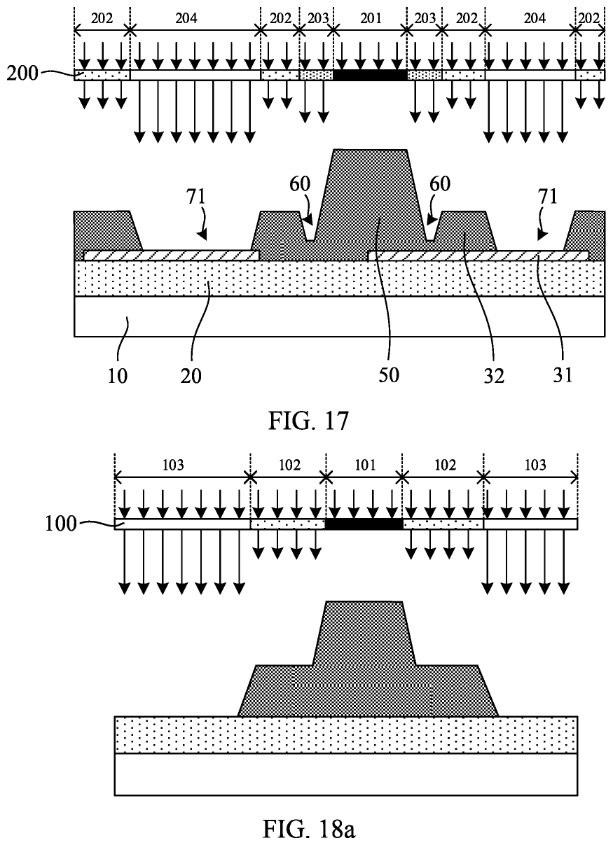

FIG. 17 is a schematic diagram of another exposure mode in accordance with an exemplary example of the present disclosure. As shown in FIG. 17, a gray tone mask 200 used for exposure may at least include a non-exposure area 201, a first partial exposure area 102, a second partial exposure area 203 and a full exposure area 204. Exposure light is not transmitted through the non-exposure area 201 so as not to expose the pixel definition thin film corresponding to this area. About half of the exposure light is transmitted through the first partial exposure area 202 so as to expose the pixel definition thin film of about half thickness corresponding to this area. About ¾ of the exposure light is transmitted through the second partial exposure area 203 so as to expose the pixel definition thin film of about ¾ of thickness corresponding to this area. The exposure light is transmitted completely through the full exposure area 204 so as to fully expose the pixel definition thin film corresponding to this area.

In an exemplary embodiment, the non-exposure area 201 may correspond to an area where the photo spacer 50 is located to form the pattern of the photo spacer 50. The first partial exposure area 202 may correspond to an area where the pixel definition layer 32 is located to form the pattern of the pixel definition layer 32. The second partial exposure area 203 may correspond to an area where the groove 60 is located to form the pattern of the groove 60, the bottom wall of the groove 60 overlays the third protrusion 92-3. The full exposure area 204 may correspond to an area where the pixel openings 71 are located to form patterns of the pixel openings 71, and the pixel openings 71 expose the surface of the body portion of the anode.

In an exemplary embodiment, four exposure areas are provided on the gray tone mask so as to ensure that the thickness of the bottom wall of the groove meets the requirements. The bottom wall of the groove can be guaranteed to overlay the protrusion of the anode even if the width of the protrusion is larger.

In an exemplary embodiment, the pixel definition layer may be made of polyimide, acrylic, polyethylene terephthalate, or the like, the present disclosure is not limited thereto.

A subsequent manufacturing process may include forming patterns of an organic light emitting layer and a cathode to form an encapsulation structure, which will not be repeated herein.

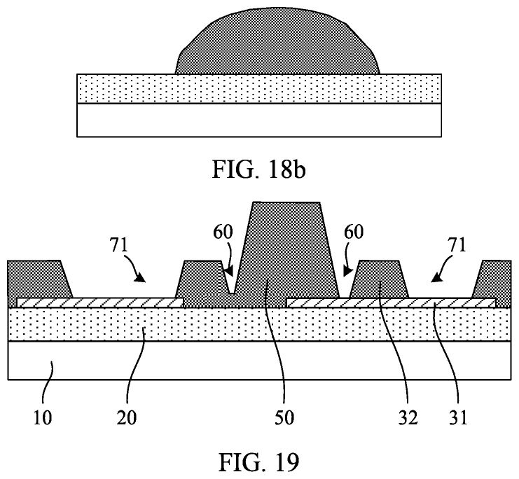

In a display substrate, the pixel definition layer and the photo spacer are separately formed through two separate runnings of patterning processes. The pixel definition layer is formed through one running of the patterning process first, and the photo spacer is formed on the pixel definition layer through another running of the patterning process. In order to shorten the process time and reduce the number of masks, in another display substrate, the pixel definition layer and the photo spacer are simultaneously formed through one running of the patterning process such as halftone mask. FIG. 18a is a schematic diagram of an exposure mode of a pixel definition layer and a photo spacer in the prior art, and FIG. 18b is a schematic sectional view of a pixel definition layer and a photo spacer in the prior art. The halftone mask 100 used for exposure includes a non-exposure area 101, a partial exposure area 102 and a full exposure area 103. The non-exposure area 101 corresponds to an area in which the photo spacer 50 is located, the partial exposure area 102 corresponds to an area in which the pixel definition layer 32 is located, and the full exposure area 103 corresponds to an area in which the pixel openings 71 are located. The inventor of the present application found, after research, that due to the flowability of the pixel definition thin film, there is no boundary at all between the cured pixel definition layer and the photo spacer, the appearance of the photo spacer is poor, and its overall height is slightly small. The photo spacer with a small height results in not only poor support effect but also defects such as Newton ring.

In the display substrate in accordance the exemplary example of the present disclosure, the groove surrounding the photo spacer is formed at a periphery of the photo spacer by adjusting the position of the full exposure area in the halftone mask. The groove can prevent the pixel definition thin film from flowing in a subsequent oven process, such that combined with exposure control in the process, there is a clear boundary between the cured pixel definition layer and the photo spacer, the appearance of the photo spacer is good, its overall height is relatively large, and the height of the photo spacer meets the requirements, to not only improve the support effect, but also avoid occurrence of defects such as Newton ring, thereby improving the product quality and display quality.

FIG. 19 is schematic diagram of a display substrate in which light leakage occurs. In an exemplary embodiment, an anode in FIG. 19 may be in the structure shown in FIG. 11b. The anode 31 may include a body portion 91 and a protrusion 92. The strip-shaped protrusion 92 has an equal-width design. An orthographic projection of groove 60 on a base substrate overlaps at least partially with an orthographic projection of the protrusion 92 of the anode 31 on the base substrate to form a connection overlapping region. The inventor of the present application found, after research, that because the width of the protrusion 92 in the connection overlapping region is larger, reflection of exposure light off the protrusion 92 increases the exposure degree of the connection overlapping region. The exposure degree of a pixel definition thin film in the connection overlapping region is relatively high, so that the pixel definition thin film in the connection overlapping region is completely removed to expose a surface of the protrusion 92. Because an organic light emitting layer formed subsequently is connected to the protrusion 92, light is emitted from the connection overlapping region, resulting in the problem of light leakage.

In a display substrate in accordance with an exemplary example of the present disclosure, a shape and a position of the photo spacer are designed such that there is no overlap between the orthographic projection of the groove on the base substrate and the orthographic projection of the protrusion of the anode on the base substrate, thereby effectively avoiding exposure of the surface of the protrusion and effectively avoiding the problem of light leakage.

In another display substrate in accordance with an exemplary example of the present disclosure, when the orthographic projection of the groove on the base substrate overlaps with the orthographic projection of the protrusion of the anode on the base substrate, the protrusion of the anode is designed purposefully such that a width of a portion of the protrusion is reduced, the area of the connection overlapping region is reduced, the reflection of the exposure light off the protrusion is reduced, and the exposure degree of the pixel definition thin film in the connection overlapping region is effectively decreased, so as to ensure that the bottom wall of the groove can overlay the protrusion, to prevent light from being emitted from the connection overlapping region, thereby eliminating the problem of light leakage and improving the display quality.

In another display substrate in accordance with an exemplary example of the present disclosure, when the orthographic projection of the groove on the base substrate overlaps with the orthographic projection of the protrusion of the anode on the base substrate, the protrusion of the anode is designed to be severed, and a connection electrode arranged in the driving circuit layer is connected to the severed protrusion, so that there is no overlap between the orthographic projection of the groove on the base substrate and the orthographic projection of the protrusion of the anode on the base substrate, thereby effectively avoiding exposure of the surface of the protrusion and effectively avoiding the problem of light leakage.

In another display substrate in accordance with an exemplary example of the present disclosure, when the orthographic projection of the photo spacer on the base substrate overlaps with the orthographic projection of the protrusion of the anode on the base substrate, the groove is eliminated in the connection overlapping region, that is, the groove is formed in an area other than the area where the protrusion is located, and the groove is not formed in the area where the protrusion is located, so that there is no overlap between the orthographic projection of the groove on the base substrate and the orthographic projection of the protrusion of the anode on the base substrate, thereby effectively avoiding exposure of the surface of the protrusion and effectively avoiding the problem of light leakage.

In another display substrate in accordance with an exemplary example of the present disclosure, when the orthographic projection of the groove on the base substrate overlaps with the orthographic projection of the protrusion of the anode on the base substrate, the exposure degree of the pixel definition thin film in the connection overlapping region can be effectively decreased by roughening the surface of the protrusion to form diffuse reflection using the roughened surface, so as to ensure that the bottom wall of the groove can overlay the protrusion, to prevent light from being emitted from the connection overlapping region, thereby eliminating the problem of light leakage and improving the display quality.

It can be seen from the structure and manufacturing process of the display substrate described above that in the present disclosure, the groove is formed at the periphery of the photo spacer so as to ensures that the height and appearance of the photo spacer meet the requirements, thereby not only improving the support effect, but also avoiding occurrence of defects such as Newton ring. In the present disclosure, the problem of light leakage is effectively avoided and the display quality is improved by preventing the groove from overlapping with the protrusion of the anode, or reducing the area where the groove overlaps with the protrusion of the anode, or decreasing the exposure degree of the pixel definition film in the connection overlapping region. The manufacturing method in accordance with the present disclosure requires less improvements on the processes, has high compatibility and processes which are simple and easy to implement, and achieves high production efficiency, low production cost and high yield rate.

The present disclosure further provides a method for manufacturing a display substrate. In an exemplary embodiment, the display substrate includes multiple pixel light emitting regions and multiple pixel spacer regions located between adjacent pixel light emitting regions. The method for manufacturing the display substrate may include:
forming a light emitting structure layer on a base substrate, wherein the light emitting structure layer at least includes an anode, a pixel definition layer and at least one photo spacer, a pixel opening is provided in the pixel definition layer in each of the pixel light emitting regions, the pixel opening exposes the anode, a spacer opening is provided in the pixel definition layer in each of the pixel spacer regions, the photo spacer is provided in the spacer opening, and an orthographic projection of the photo spacer on the base substrate is within a range of an orthographic projection of the spacer opening on the base substrate.

The present disclosure further provides a display device which includes the display substrate describe above. The display device may be any product or component with a display function, such as a mobile phone, a tablet computer, a television, a display, a laptop computer, a digital photo frame, a navigator, a vehicle-mounted display, a smart watch or a smart bracelet.

Although the embodiments of the present disclosure are disclosed as above, the contents described are intended to only for ease of understanding of the embodiments of the present disclosure, rather than limiting the present disclosure. Any skilled person in the art to which the present disclosure pertains may make any modification and alteration in forms and details of implementation without departing from the spirit and scope of the present disclosure. However, the patent protection scope of the present disclosure should be subject to the scope defined by the appended claims.

1. A display substrate comprising a plurality of pixel light emitting regions and a plurality of pixel spacer regions located between adjacent pixel light emitting regions; in a plane perpendicular to the display substrate, the display substrate comprises a base substrate and a light emitting structure layer disposed on the base substrate, the light emitting structure layer at least comprises an anode, a pixel definition layer and at least one photo spacer, a pixel opening is provided in the pixel definition layer in each of the pixel light emitting regions, the pixel opening exposes the anode, a spacer opening is provided in the pixel definition layer in each of the pixel spacer regions, the photo spacer is provided in the spacer opening, and an orthographic projection of the photo spacer on the base substrate is within a range of an orthographic projection of the spacer opening on the base substrate.

2. The display substrate according to claim 1, wherein a groove is provided between a sidewall of the photo spacer and a sidewall of the spacer opening.

3. The display substrate according to claim 2, wherein a transverse distance between the sidewall of the photo spacer and the sidewall of the spacer opening gradually increases along a direction away from the base substrate, and the transverse distance is a dimension in a plane parallel to the display substrate.

4. The display substrate according to claim 2, wherein at least one anode comprises a body portion and at least one protrusion, the pixel opening exposes the body portion of the anode, and there is no overlap between an orthographic projection of the groove on the base substrate and an orthographic projection of the at least one protrusion of the anode on the base substrate.

5. (canceled)

6. The display substrate according to claim 4, wherein an orthographic projection of the protrusion on the base substrate overlaps at least partially with the orthographic projection of the photo spacer on the base substrate, and the groove is in a shape of letter “C”, and is provided in an area other than an area where the protrusion is located.

7-10. (canceled)

11. The display substrate according to claim 2, wherein a width of a surface of the groove close to the base substrate is 0.5 μm to 5.0 μm, and the width is a dimension perpendicular to an extension direction of the groove.

12. (canceled)

13. The display substrate according to claim 1, wherein the photo spacer and the pixel definition layer are made of a same material, and are formed simultaneously through the same running of a patterning process.

14. The display substrate according to claim 1, further comprising a driving circuit layer disposed on the base substrate, wherein the light emitting structure layer is disposed on one side of the driving circuit layer away from the base substrate; the driving circuit layer comprises a plurality of circuit units constituting a plurality of rows of units and a plurality of columns of units, the plurality of circuit units are arranged in alignment in the rows of units, and the plurality of circuit units is arranged in alignment in the columns of units; the light emitting structure layer comprises a plurality of sub-pixels constituting a plurality of rows of pixels and a plurality of columns of pixels, the plurality of sub-pixels are arranged in alignment in the rows of pixels, and the plurality of sub-pixels are arranged in a staggered manner in the columns of pixels.

15. The display substrate according to claim 14, wherein at least one of the circuit units comprises a pixel driving circuit, the pixel driving circuit is connected to a first scan signal line, a second scan signal line and a light emitting control line respectively, the pixel driving circuit at least comprises a storage capacitor, in the M-th row of units, the first scan signal line is located at one side of the storage capacitor close to the (M+1)-th row of units, the second scan signal line is located at one side of the storage capacitor away from the (M+1)-th row of units, and the light emitting control line is located between the storage capacitor and the second scan signal line; at least one of the sub-pixels comprises an anode connected to the pixel driving circuit, an anode in the (2M−1)-th row of pixels is located at one side of the light emitting control line in the M-th row of units away from the (M+1)-th row of units, an anode in the 2M-th row of pixels is located at one side of the light emitting control line in the M-th row of units close to the (M+1)-th row of units, 1≤M≤K, and K is the number of the rows of units.

16. The display substrate according to claim 15, wherein an orthographic projection of the anode in the (2M−1)-th row of pixels on the base substrate overlaps at least partially with an orthographic projection of the second scan signal line in the M-th row of units on the base substrate, and an orthographic projection of the anode in the 2M-th row of pixels on the base substrate overlaps at least partially with an orthographic projection of the storage capacitor on the base substrate.

17. The display substrate according to claim 15, wherein an orthographic projection of the anode in the (2M−1)-th row of pixels on the base substrate overlaps at least partially with an orthographic projection of two pixel driving circuits in the M-th row of units on the base substrate, and an orthographic projection of the anode in the 2M-th row of pixels on the base substrate overlaps at least partially with the orthographic projections of two pixel driving circuits in the M-th row of units on the base substrate.

18. The display substrate according to claim 15, wherein at least one photo spacer being located between adjacent anodes comprises any one or more of the following cases that: at least one photo spacer is located between adjacent anodes in a row of pixels, at least one photo spacer is located between adjacent anodes in a column of pixels, and at least one photo spacer is located between the anode in the (2M−1)-th row of pixels and the anode in the 2M-th row of pixels.

19. The display substrate according to claim 15, wherein the at least one photo spacer is in a shape of a rectangle, which comprises long sides and short sides, and each photo spacer at least comprises a first photo spacer with long sides extending along a direction of the columns of pixels, a second photo spacer with long sides extending along a direction of the rows of pixels, and a third photo spacer with long sides extending along an oblique direction, a first included angle is formed between the oblique direction and the direction of the columns of pixels, or a second included angle is formed between the oblique direction and the direction of the rows of pixels, and the first included angle and the second included angle are greater than 0° and less than 90°.

20. The display substrate according to claim 19, wherein the first photo spacer is arranged between adjacent anodes in a row of pixels, the second photo spacer is arranged between adjacent anodes in a row of pixels, and the third photo spacer is arranged between the anode in the (2M−1)-th row of pixels and the anode in the 2M-th row of pixels.

21. The display substrate according to claim 19, wherein an orthographic projection of the third photo spacer on the base substrate overlaps at least partially with an orthographic projection of the light emitting control line on the base substrate.

22. The display substrate according to claim 14, wherein a plurality of photo spacers constitutes a plurality of rows of photo spacers and a plurality of columns of photo spacers, and three rows of pixels correspond to four rows of photo spacers.

23. A display device comprising the display substrate according to claim 1.

24. A method for manufacturing a display substrate, which comprises a plurality of pixel light emitting regions and a plurality of pixel spacer regions located between adjacent pixel light emitting regions, the method comprising:
forming a light emitting structure layer on a base substrate, the light emitting structure layer at least comprising an anode, a pixel definition layer and at least one photo spacer, a pixel opening being provided in the pixel definition layer in each of the pixel light emitting regions, the pixel opening exposing the anode, a spacer opening being provided in the pixel definition layer in each of the pixel spacer regions, the photo spacer being provided in the spacer opening, and an orthographic projection of the photo spacer on the base substrate being within a range of an orthographic projection of the spacer opening on the base substrate.

25. The display substrate according to claim 2, further comprising a driving circuit layer disposed on the base substrate, wherein the light emitting structure layer is disposed on one side of the driving circuit layer away from the base substrate; the driving circuit layer comprises a plurality of circuit units constituting a plurality of rows of units and a plurality of columns of units, the plurality of circuit units are arranged in alignment in the rows of units, and the plurality of circuit units is arranged in alignment in the columns of units; the light emitting structure layer comprises a plurality of sub-pixels constituting a plurality of rows of pixels and a plurality of columns of pixels, the plurality of sub-pixels are arranged in alignment in the rows of pixels, and the plurality of sub-pixels are arranged in a staggered manner in the columns of pixels.

26. The display substrate according to claim 3, further comprising a driving circuit layer disposed on the base substrate, wherein the light emitting structure layer is disposed on one side of the driving circuit layer away from the base substrate; the driving circuit layer comprises a plurality of circuit units constituting a plurality of rows of units and a plurality of columns of units, the plurality of circuit units are arranged in alignment in the rows of units, and the plurality of circuit units is arranged in alignment in the columns of units; the light emitting structure layer comprises a plurality of sub-pixels constituting a plurality of rows of pixels and a plurality of columns of pixels, the plurality of sub-pixels are arranged in alignment in the rows of pixels, and the plurality of sub-pixels are arranged in a staggered manner in the columns of pixels.
